(19) United States
(12) Patent Application Publication
(10) Pub. No.: US 2026/0255973 A1
(43) Pub. Date: Aug. 27, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Chih-Ping CHANG, Tainan City (TW); Hsin-Ting CHEN, Tainan City (TW); Ming-I WANG, Tainan City (TW); Shyh-Fann TING, Tainan City (TW)

(21) Appl. No.: 19/236,323

(22) Filed: Jun. 12, 2025

Related U.S. Application Data
(60) Provisional application No. 63/760,946, filed on Feb. 20, 2025.

(51) Int. Cl. H10W 42/00; H10P 54/00

(52) U.S. Cl. CPC H10W 42/00; H10P 54/00

(57) ABSTRACT

Semiconductor devices are manufactured on a wafer to include one or more buffer regions that may be used for dicing or cutting the semiconductor devices from the wafer in a die singulation process. The buffer region(s) of a semiconductor device may be located between a scribe line region of the wafer and a seal ring region of the semiconductor device. A laser beam may be used to cut a groove into the buffer region(s) of the semiconductor device as opposed to cutting the groove into the scribe line regions of the wafer. Another laser beam and/or a wafer saw may then be used to cut fully through the scribe line regions to dice or cut the wafer into individual semiconductor devices.

### CROSS-REFERENCE TO RELATED APPLICATION

This Patent Application claims priority to U.S. Provisional Patent Application No. 63/760,946, filed on Feb. 20, 2025, and entitled “SEMICONDUCTOR DEVICE AND METHODS OF FORMATION.” The disclosure of the prior Application is considered part of and is incorporated by reference into this Patent Application.

### BACKGROUND

A plurality of semiconductor devices are often manufactured on a single wafer such as a silicon (Si) wafer. Manufacturing a plurality of semiconductor devices on the same wafer enables manufacturing operations such as deposition, lithography patterning, and/or etching to be shared across the semiconductor devices, which reduces processing time, cost, and complexity for high-volume semiconductor device manufacturing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of an example of a semiconductor device described herein.

FIGS. 2A and 2B illustrate an example of semiconductor devices formed on a wafer.

FIGS. 3A-3C are diagrams of an example implementation of forming semiconductor devices on a wafer described herein.

FIGS. 4A-4G are diagrams of an example implementation of a die singulation process for singulating semiconductor devices from a wafer described herein.

FIGS. 5A-5G are diagrams of an example implementation of a die singulation process for singulating semiconductor devices from a wafer described herein.

FIGS. 6A-6D are diagrams of example implementations of semiconductor devices singulated from a wafer described herein.

FIGS. 7A-7F are diagrams of an example implementation of a die singulation process for singulating semiconductor devices from a wafer described herein.

FIG. 8 is a flowchart of an example process associated with forming a plurality of semiconductor devices on a wafer described herein.

FIG. 9 is a flowchart of an example process associated with forming a plurality of semiconductor devices on a wafer described herein.

FIGS. 10A-10F are diagrams of an example implementation of a die singulation process for singulating semiconductor devices from a wafer described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

At a point during manufacturing of semiconductor devices on a wafer, the wafer may be diced or cut to singulate the semiconductor devices. Additional processing of the semiconductor devices may be performed after singulation, such as testing and packaging. The wafer may include scribe line regions, which are regions of the wafer around the semiconductor devices that are manufactured to provide a dedicated area of the wafer through which the wafer may be cut. In some cases, the scribe line region of a wafer may include structures for other purposes such as process control monitoring (PCM) structures that are used to monitor various aspects of the semiconductor devices during manufacturing.

Various die singulation techniques may be used to dice or cut a wafer into individual semiconductor devices. For example, a diamond-coated saw may be used to cut through (e.g., by sawing) scribe line regions of the wafer. As another example, a laser beam maybe used to cut through (e.g., by laser cutting) scribe line regions of the wafer. In some cases, a combination of laser cutting and sawing is used to cut through the scribe line regions of a wafer to cut the wafer into individual semiconductor devices.

The process of cutting a wafer into individual semiconductor devices can cause manufacturing defects in the semiconductor devices because of the mechanical stresses induced in various areas of the semiconductor devices from sawing and/or laser cutting, among other examples. For example, the process of cutting a wafer into individual semiconductor devices generates debris from removing material from the scribe line regions of the wafer, and the debris may damage the semiconductor devices through mechanical abrasion of layers and/or structures of the semiconductor devices. As another example, the process of cutting a wafer into individual semiconductor devices generates heat and vibration in the structures in the scribe line regions of the wafer, which can propagate into the layers and/or structures in functional device areas of the semiconductor devices and weaken and/or damage those layers and/or structures. These and other mechanical stresses induced in various areas of the semiconductor devices from the singulation process may lead to cracking, delamination, and/or other types of physical damage to the layers and/or structures of the semiconductor devices.

In some implementations described herein, semiconductor devices are manufactured on a wafer to include one or more buffer regions that may be used for dicing or cutting the semiconductor devices from the wafer in a die singulation process. The buffer region(s) of a semiconductor device may be located between a scribe line region of the wafer and a seal ring region of the semiconductor device. The seal ring region may laterally surround a device region of the semiconductor device, and the buffer region(s) may laterally surround the seal ring region of the semiconductor device.

In a die singulation process, a laser beam may be used to cut a groove into the buffer region(s) of the semiconductor device as opposed to cutting the groove into the scribe line regions of the wafer. Another laser beam and/or a wafer saw may then be used to cut fully through the scribe line regions to dice or cut the wafer into individual semiconductor devices.

The pattern density (e.g., the density of structures) in the buffer region(s) is less than the pattern density in the scribe line regions and in the device region. The lower pattern density in the buffer region(s) provides fewer paths through which heat and mechanical vibration from laser cutting and/or sawing can propagate into the device region of the semiconductor device. In other words, the buffer region(s) effectively provide a buffer for the device region from heat and mechanical stresses generated during the die singulation process, which reduces the likelihood that these other mechanical stresses generated from the die singulation process may lead to cracking, delamination, and/or other types of physical damage to the layers and/or structures of the semiconductor devices. In this way, the buffer region(s) described herein may reduce the defect rate, increase reliability, and/or increase the yield for semiconductor devices manufactured on the wafer.

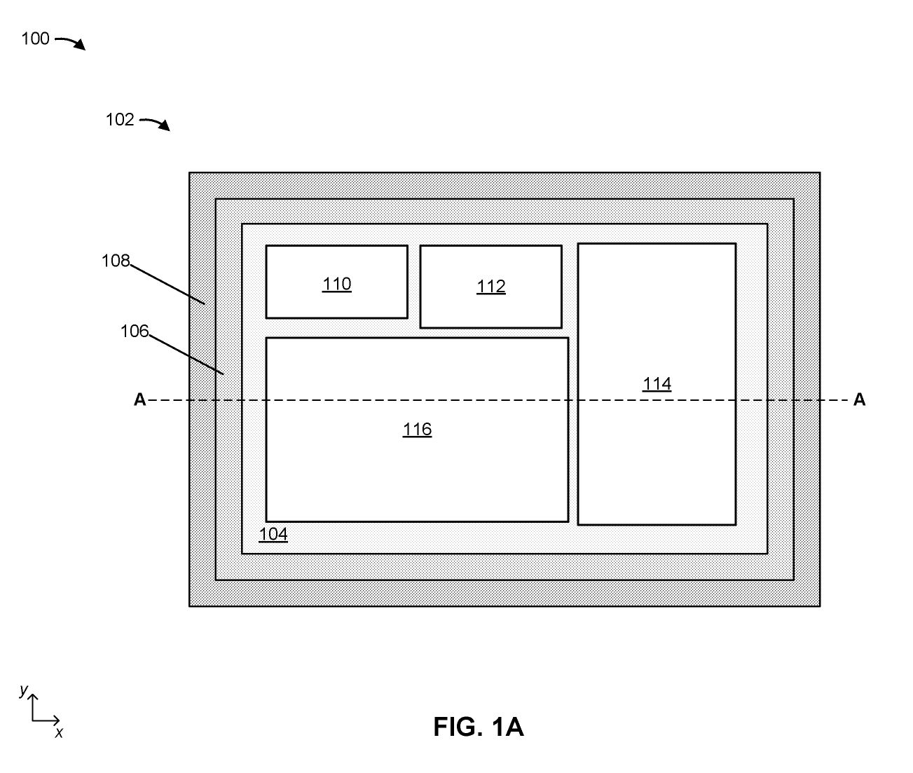

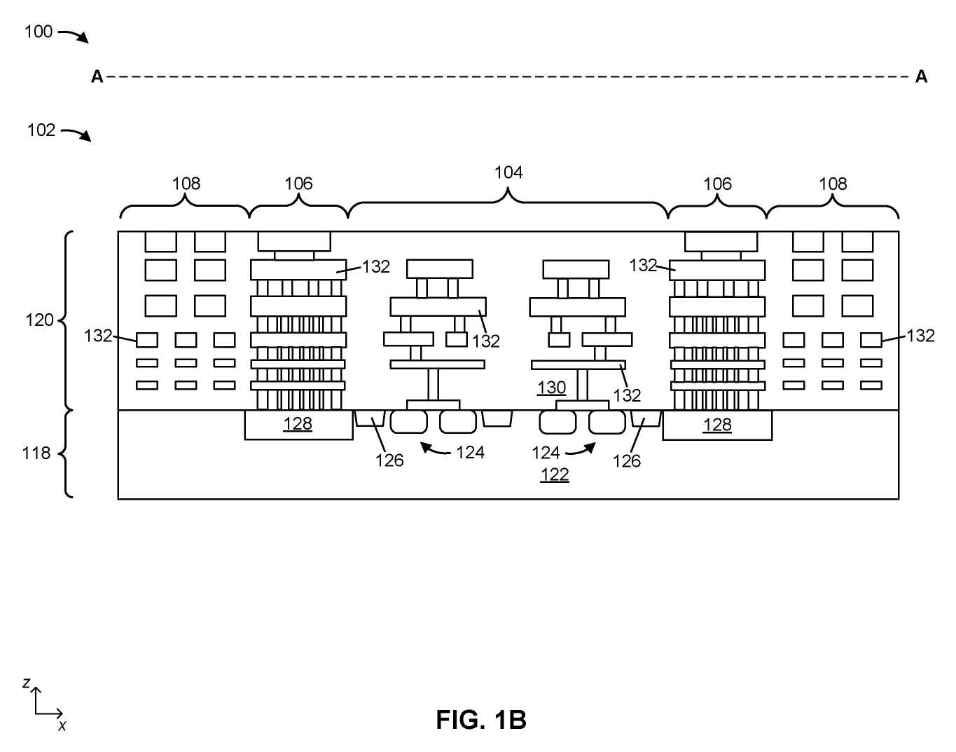

FIGS. 1A and 1B are diagrams of an example 100 of a semiconductor device 102 described herein. FIG. 1A illustrates a top view of the semiconductor device 102, and FIG. 1B illustrates a cross-section view of the semiconductor device 102 along the line A-A in FIG. 1A.

As shown in FIG. 1A, the semiconductor device 102 may include a device region 104, a seal ring region 106 around the device region 104, and a buffer region 108 around the seal ring region 106.

The device region 104 may correspond to the active region of the semiconductor device 102. The semiconductor device 102 may be a system-on-chip (SoC) die, a central processing unit (CPU) die, a graphics processing unit (GPU) die, a digital signal processing (DSP) die, an application specific integrated circuit (ASIC) die, an image sensor die, an HPC die, and/or another type of semiconductor die that includes a plurality of functional regions 110-116 that are laterally distributed across the device region 104. The top view layout and the quantity, sizes, shapes, and/or arrangements of functional regions 110-116 in the semiconductor device 102 are examples, and other layouts, quantities, sizes, shapes, and/or arrangements are within the scope of the present disclosure.

Each of the functional regions 110-116 may be manufactured to include integrated circuits that are configured to perform a particular set of functions of the semiconductor device 102. For example, the functional region 110 may be a memory region (or a memory core) of the semiconductor device 102 that includes integrated circuitry configured to perform memory functions of the semiconductor device 102. As another example, the functional region 112 may be an analog circuitry region (or an analog core) of the semiconductor device 102 that includes integrated circuitry configured to perform analog functions of the semiconductor device 102. As another example, the functional region 114 may be an RF circuitry region (or an RF core) of the semiconductor device 102 that includes integrated circuitry configured to perform RF communication functions of the semiconductor device 102. As another example, the functional region 116 may be a logic circuitry region (or a logic core) of the semiconductor device 102 that includes integrated circuitry configured to perform logic functions of the semiconductor device 102. In some implementations, the semiconductor device 102 includes another type of functional region or a different combination of functional regions.

As further shown in FIG. 1A, the seal ring region 106 may laterally surround the functional regions 110-116 of the semiconductor device 102. The seal ring region 106 may include a ring of interconnected layers of metallization structures and interconnect structures that provide increased structural rigidity for the semiconductor device 102, which may reduce the likelihood of cracking, warpage, and/or another type of physical damage that might otherwise result from physical stresses that are exerted on the semiconductor device 102. Additionally and/or alternatively, the interconnected layers of the seal ring region 106 may be configured to provide a humidity seal for the semiconductor device 102, which may reduce the likelihood of humidity ingress in the semiconductor package. The interconnected layers of metallization structures may form a continuous seal around the perimeter of the device region 104 of the semiconductor device 102.

As further shown in FIG. 1A, the buffer region 108 may laterally surround the seal ring region 106. The buffer region 108 may include an annular region of the semiconductor device 102 that buffers the device region 104 and the seal ring region 106 from a scribe line region of a wafer on which the semiconductor device 102 was formed. The buffer region 108 may inhibit disturbances such as vibration and heat from reaching the device region 104 and damaging the integrated circuit devices therein.

The buffer region 108 may be a non-functional region of the semiconductor device 102 that includes a ring of metallization structures around the seal ring region 106. The density of metallization structures in the buffer region 108 may be less than the density of metallization structures in the seal ring region 106 to provide fewer paths through which vibration and heat may propagate to the device region 104.

As shown in FIG. 1B, the semiconductor device 102 may include a device layer 118 and an interconnect layer 120 above the device layer 118. In some implementations, the semiconductor device 102 includes interconnect layers 120 on the top and bottom sides of the device layer 118 so that signals and/or power may be distributed on both sides of the device layer 118.

The device layer 118 may include a substrate layer 122. The substrate layer 122 may correspond to a portion of a wafer on which the semiconductor device 102 was formed. The substrate layer 122 may include a silicon (Si) substrate, a substrate formed of a material including silicon, a III-V compound semiconductor material substrate such as gallium arsenide (GaAs), a silicon-on-insulator (SOI) substrate, or another type of wafer.

The device layer 118 may further include one or more integrated circuit devices 124 in and/or on the frontside of the substrate layer 122. The integrated circuit devices 124 may each include transistors (e.g., planar transistors, fin field effect transistors (finFETs), gate all around (GAA) transistors), pixel sensors, capacitors, resistors, inductors, photodetectors, transceivers, transmitters, receives, optical circuits, diodes, and/or other types of passive and/or active integrated circuit devices.

Isolation regions 126 may also be included in the substrate layer 122 to provide electrical isolation for the integrated circuit devices 124. One or more isolation regions 126 may include implant regions of the substrate layer 122 in which dopants were implanted. The dopants may include, for example n-type dopants (such as phosphorous (P) and/or arsenic (As) and/or p-type dopants (such as boron (B)). Additionally and/or alternatively, one or more of the isolation regions 126 may include shallow trench isolation (STI) structures. An STI structure may be a dielectric structure that extends into the frontside of the substrate layer 122, and may include one or more dielectric materials such as a silicon oxide material (SiOₓ such as SiO₂), a silicon nitride material (SiₓN_{y} such Si₃N₄), and/or another suitable dielectric material.

In the seal ring region 106, one or more isolation regions 128 may be included in the substrate layer 122 to provide electrical isolation for the integrated circuit devices 124 from external effects such as vibration and/or humidity. One or more isolation regions 128 may include implant regions of the substrate layer 122 in which dopants were implanted. The dopants may include, for example n-type dopants (such as phosphorous (P) and/or arsenic (As) and/or p-type dopants (such as boron (B)). Additionally and/or alternatively, one or more of the isolation regions 128 may include STI structures.

The interconnect layer 120 includes a dielectric region 130 above the substrate layer 122. The dielectric region 130 may include one or more backend dielectric layers (e.g., one or more interlayer dielectric (ILD) layers, one or more intermetal dielectric (IMD) layers) and one or more etch stop layers (ESLs) that are arranged in an alternating manner in the interconnect layer 120. The dielectric layer(s) may each include an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The interconnect layer 120 further includes one or more layers of metallization structures 132 (e.g., electrically conductive structures) in the dielectric region 130. The metallization structures 132 in the device region 104 may be electrically coupled and/or physically coupled with one or more of the integrated circuit devices 124 in the device layer 118 and/or may be electrically interconnected together. The metallization structures 132 may correspond to circuit routing that enables signals and/or power to be provided to and/or from the integrated circuit devices 124. The metallization structures 132 may include a combination of metal lines that extend primarily horizontally in the interconnect layer 120, interconnect structures (e.g., vias) that extend primarily vertically in the interconnect layer 120 and electrically couple the layers of metal lines. The metallization structures 132 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

In the device region 104, the layers of metallization structures 132 may be arranged in a vertical manner to facilitate electrical signals and/or power to be routed between the device layer 118 and external connectors coupled to the semiconductor device 102. The metallization structures 132 may be arranged in alternating layers of metallization layers (referred to as “M”-layers) and via layers (referred to as “V”-layers). Each metallization layer may include one or more metallization structures 132 laterally arranged in the interconnect layer 120, and each via layer may include one or more metallization structures 132 that interconnect the metallization layers in the interconnect layer 120. As an example, a via-0 (V0) layer may be located at the bottom of the interconnect layer 120 (e.g., interfacing the frontside of the device layer 118) and may be coupled with the integrated circuit devices 124 in the substrate layer 122, a metal-0 (V0) layer may be located above and coupled with the V0 layer in the interconnect layer 120, a via-1 (V1) layer may be located above and coupled with the M0 layer in the interconnect layer 120, a metal-1 (M1) layer may be located above and coupled with the V1 layer in the interconnect layer 120, a via-2 (V2) layer may be located above and electrically coupled with the M1 layer in the interconnect layer 120, and so on. In some implementations, the interconnect layer 120 includes nine (9) stacked metallization layers (e.g., M0-M8). In other implementations, a contact layer (referred to as “CO”-layer) may be located at the bottom of the interconnect layer 120 and may be coupled with the integrated circuit devices 124 in the substrate layer 122, the V0 layer may be located above and coupled with the CO layer in the interconnect layer 120, and so on. In some implementations, the interconnect layer 120 includes another quantity of stacked metallization layers.

The seal ring region 106 may also extend vertically through the dielectric region 130 of the interconnect layer 120 and may extend laterally around the device region 104. The seal ring region 106 may include a plurality of vertically-arranged layers (e.g., in the z-direction) of metallization structures 132 that laterally surround the device region 104 of the semiconductor device 102. The plurality of vertically-arranged layers of metallization structures 132 may be located above the isolation region(s) 128 of the seal ring region 106 so that the electrical and/or environmental isolation provided by the seal ring region 106 extends through the dielectric region 130 and into the substrate layer 122.

The seal ring region 106 may be located laterally between the device region 104 and the buffer region 108. The buffer region 108 may extend vertically through the dielectric region 130 of the interconnect layer 120 and may extend laterally around the seal ring region 106. The buffer region 108 may include a plurality of vertically-arranged layers (e.g., in the z-direction) of metallization structures 132 that laterally surround the device region 104 of the semiconductor device 102. The density of metallization structures 132 in the buffer region 108 may be less than the density of metallization structures 132 in the seal ring region 106 to provide fewer paths through which vibration and heat may propagate to the device region 104.

In some implementations, the plurality of vertically-arranged layers of metallization structures 132 in the buffer region 108 are spaced apart by portions the dielectric region 130. In other words, vertically-adjacent layers of metallization structures 132 in the buffer region 108 may not be connected together. In some implementations, vertically-adjacent layers of metallization structures 132 in the buffer region 108 are connected together.

As indicated above, FIGS. 1A and 1B are provided as an example. Other examples may differ from what is described with regard to FIGS. 1A and 1B.

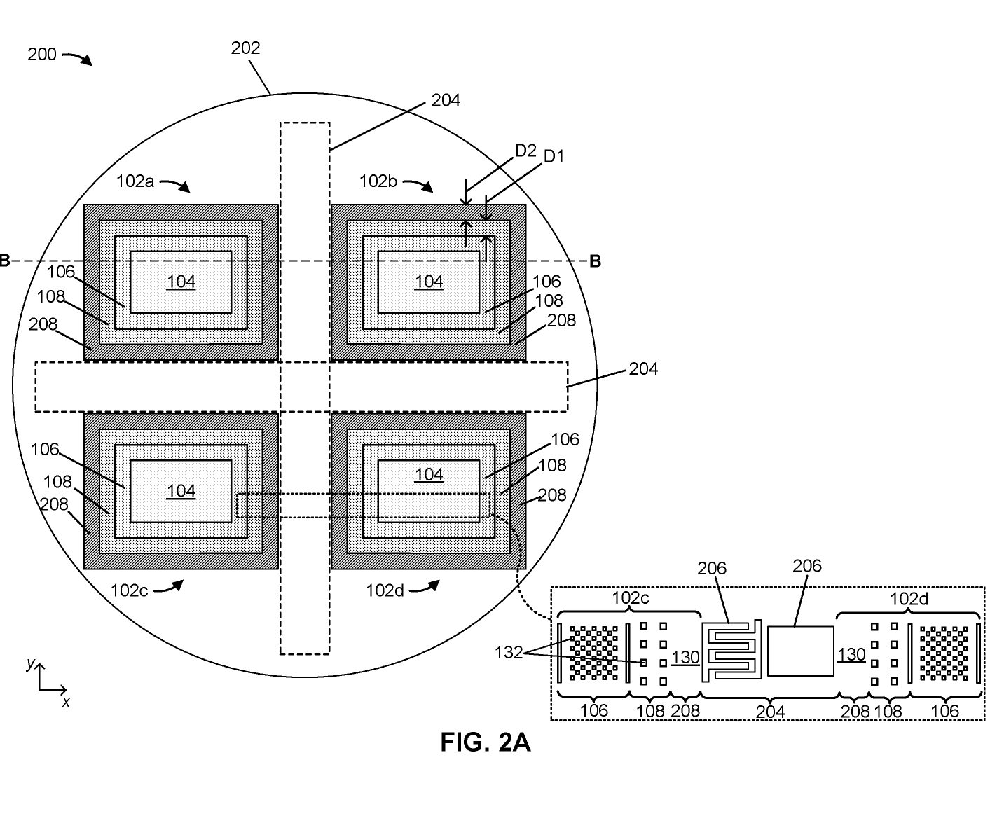

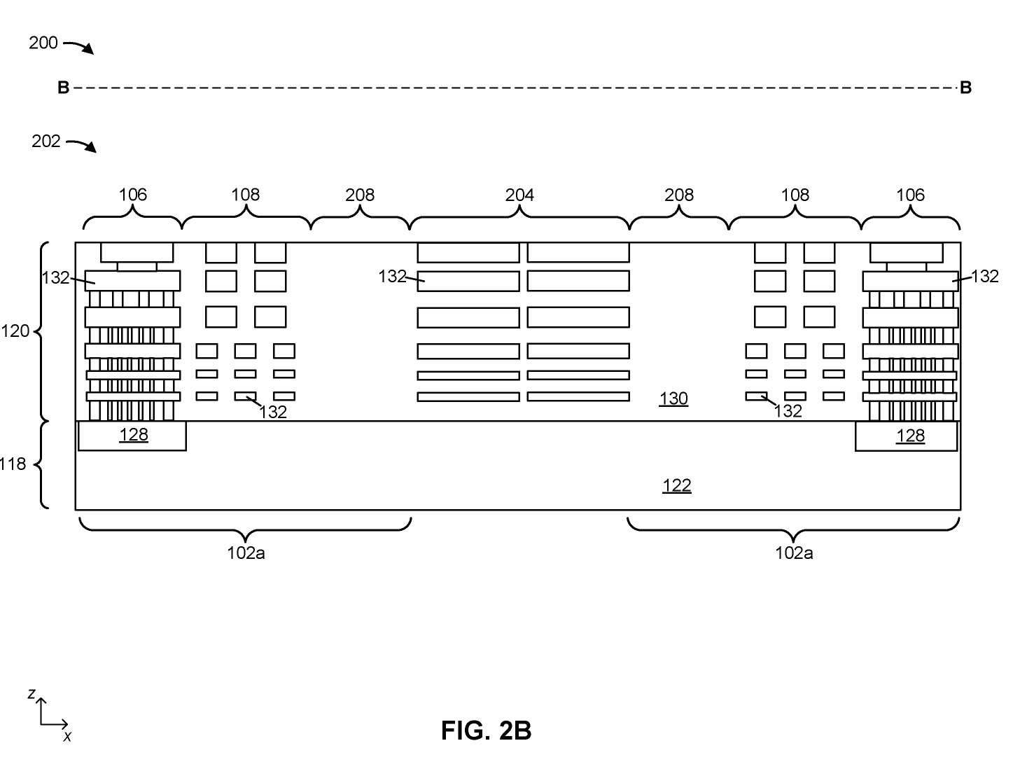

FIGS. 2A and 2B illustrate an example 200 of semiconductor devices 102 formed on a wafer 202. FIG. 2A illustrates a top view of the wafer 202, and FIG. 2B illustrates a cross-section view of the wafer 202 along the line B-B in FIG. 2A.

The wafer 202 may include a semiconductor wafer such as a silicon (Si) wafer, a silicon carbide (SiC) wafer, and/or a germanium (Ge) wafer, among other examples. In some implementations, the wafer 202 is a multi-layer wafer such as a silicon-on-insulator (SOI) wafer. In some implementations, the wafer 202 is a dielectric wafer such as a glass wafer. In some implementations, the wafer 202 is a substantially round and approximately 200 millimeters in diameter, 300 millimeters in diameter, or another diameter. In some implementations, the wafer 202 has another shape.

As shown in FIG. 2A, semiconductor devices 102a-102d may be formed on the wafer 202 such that the semiconductor devices 102a-102d are laterally spaced apart and separated by scribe line regions 204. The layout and quantity of semiconductor devices 102a-102d illustrated in FIG. 2A is an example, and other layouts and quantities are within the scope of the present disclosure.

The scribe line regions 204 are regions of the wafer 202 around the semiconductor devices 102a-102d that provide space in which the wafer 202 may be cut or diced to singulate the semiconductor devices 102a-102d into individual devices. As shown in a detailed view in FIG. 2A, in some implementations, the scribe line regions 204 may include various structures, such as test structures 206. In some implementations, the scribe line regions 204 may include other structures, such as dummy structures (e.g., non-functional structures) 208, among other examples. The test structures 206 may include process control monitoring (PCM) structures that are included to monitor aspects of the manufacturing processes performed on the wafer 202. In some implementations, the test structures 206 may include wafer acceptance testing (WAT) structures, stress testing structures, test pads, test circuits, and/or other types of test structures.

As further shown in FIG. 2A, the semiconductor devices 102a-102d may be manufactured to include a plurality of buffer regions around the device regions 104 of the semiconductor devices 102a-102d, such as the buffer region 108 around the seal ring region 106, and another buffer region 208 around the buffer region 108. The buffer region 208 may be included around the perimeter of the buffer region 108 such that the buffer region 208 laterally surrounds the buffer region 108.

A buffer region 208 of a semiconductor device 102 (e.g., the semiconductor device 102c) may be similar to the buffer region 108 and may include a portion of the dielectric region 130 of the semiconductor device 102. The densities of metallization structures 132 in the buffer regions 108 and 208 may each be less than the densities of metallization structures in the scribe line regions 204 and in the seal ring regions 106. However, the density of metallization structures 132 in the buffer region 208 is less than the density of metallization structures 132 in the buffer region 108. In some implementations, the density of metallization structures 132 in the buffer region 108 is approximately 25% to approximately 90% of the total area or volume in the buffer region 108, whereas the density of metallization structures 132 in the buffer region 208 is at least approximately 5% less than the density of metallization structures 132 in the buffer region 108. In some implementations, the buffer region 208 is free of metallization structures 132, test structures 206, and/or dummy structures; and the density of metallization structures 132 in the buffer region 208 is approximately 0%.

The buffer regions 208 of the semiconductor devices 102a-102d provide additional area through which cutting and/or sawing may be performed as part of a die singulation process for cutting the semiconductor devices 102a-102d from the wafer 202. The low pattern density (e.g., the low density of metallization structures 132) in the buffer regions 208 of the semiconductor devices 102a-102d provides fewer paths through which heat and mechanical vibration from laser cutting and/or sawing can propagate into the device regions 104 of the semiconductor devices 102a-102d during the die singulation process. In other words, the buffer regions 208 effectively provides a buffer for the device regions 104 from heat and mechanical stresses generated during the die singulation process, which reduces the likelihood that these other mechanical stresses generated from the die singulation process may lead to cracking, delamination, and/or other types of physical damage to the layers and/or structures of the semiconductor devices 102a-102d. In this way, the buffer regions 208 may reduce the defect rate, increase reliability, and/or increase the yield for semiconductor devices 102 manufactured on the wafer 202.

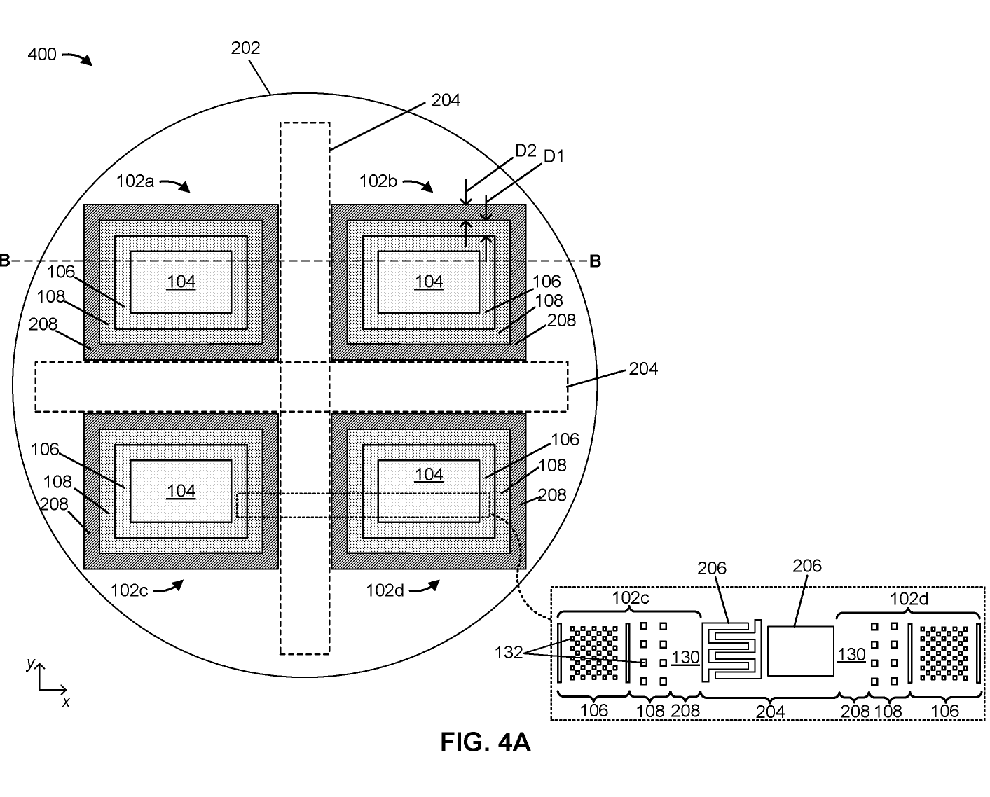

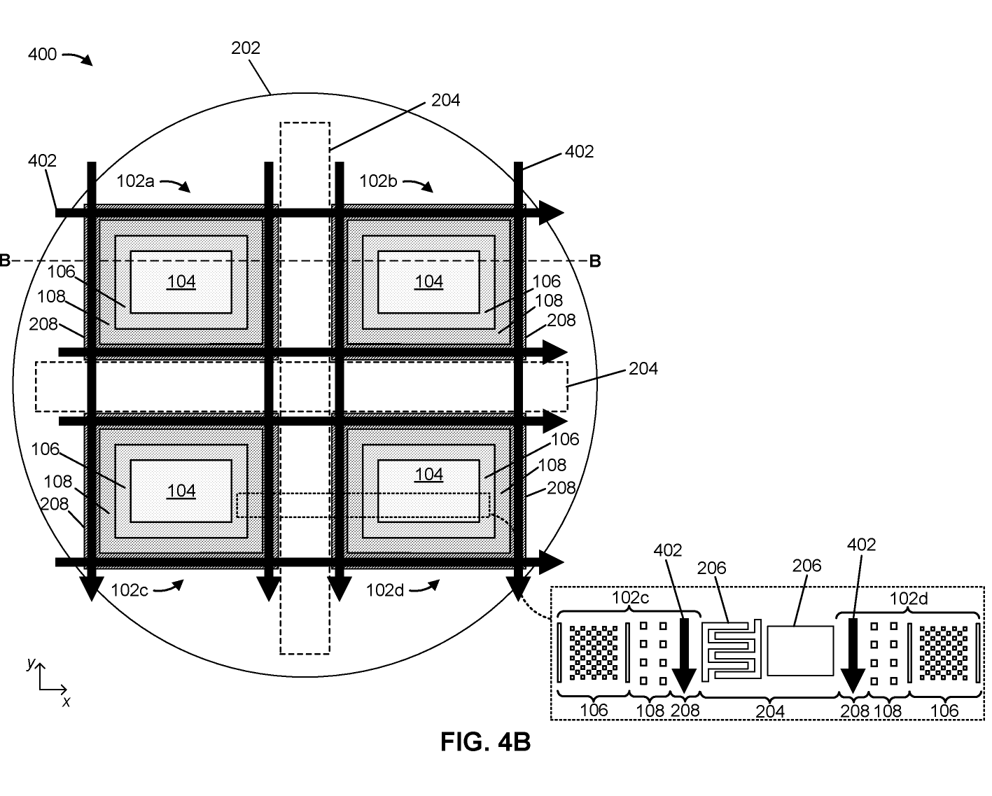

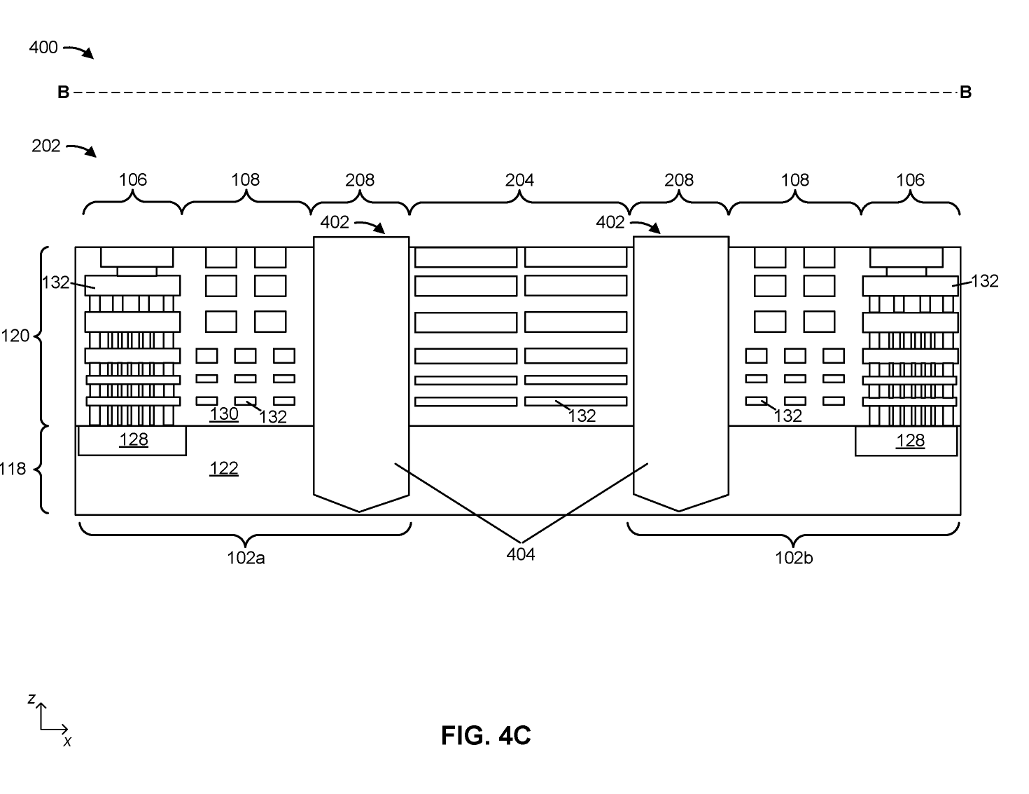

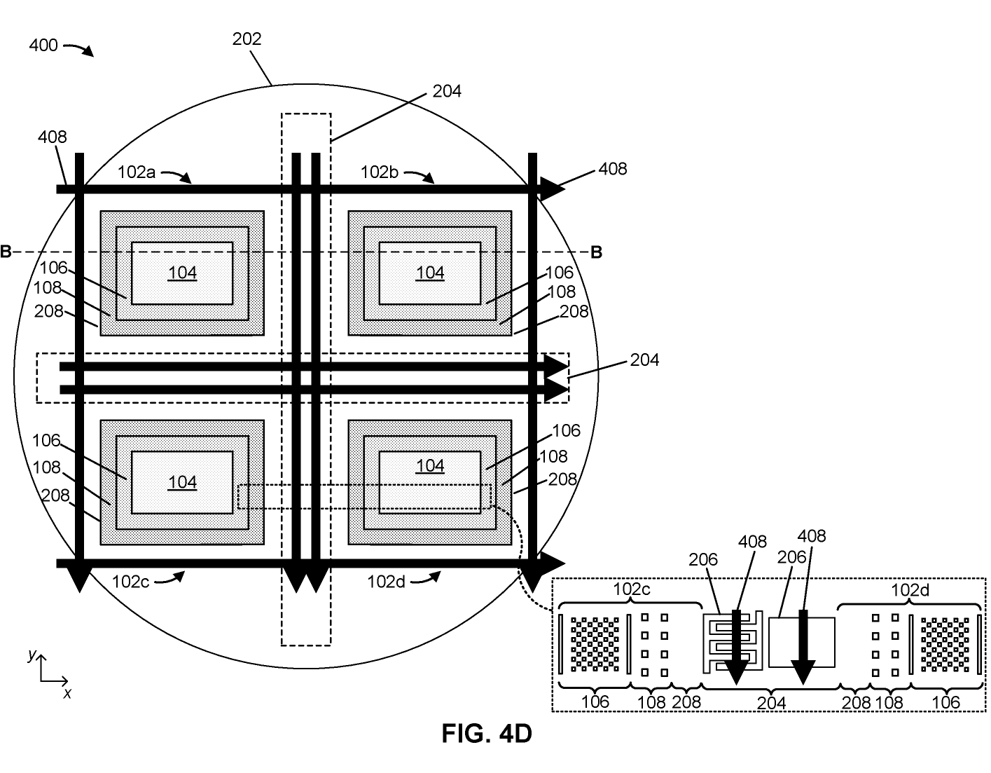

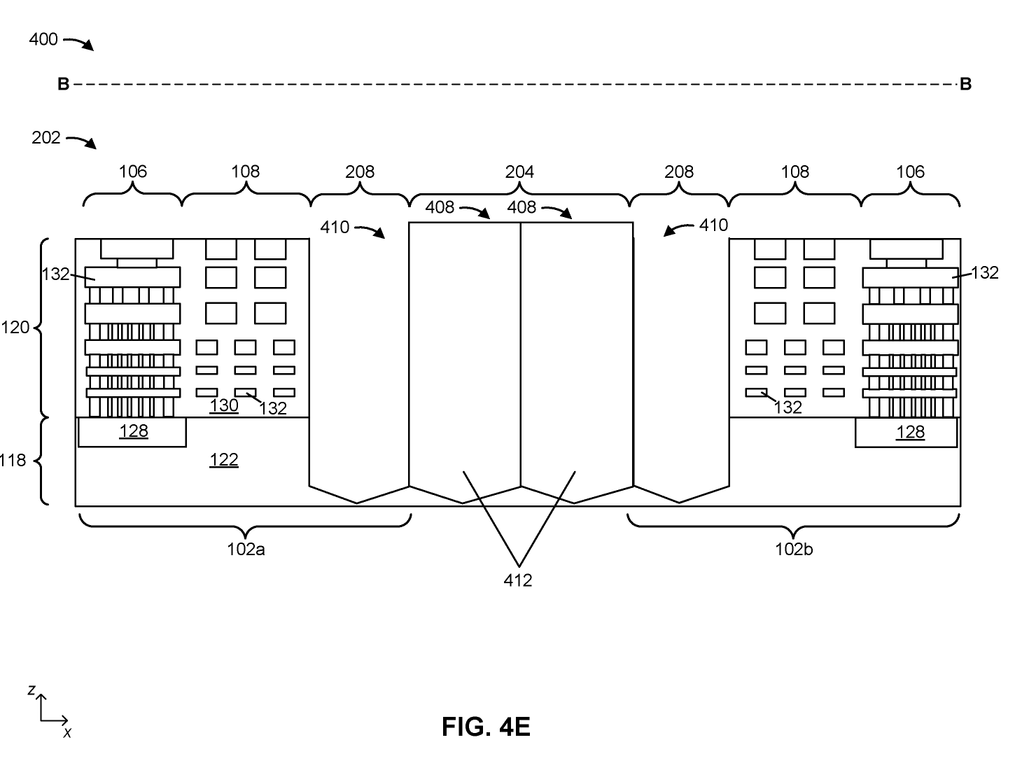

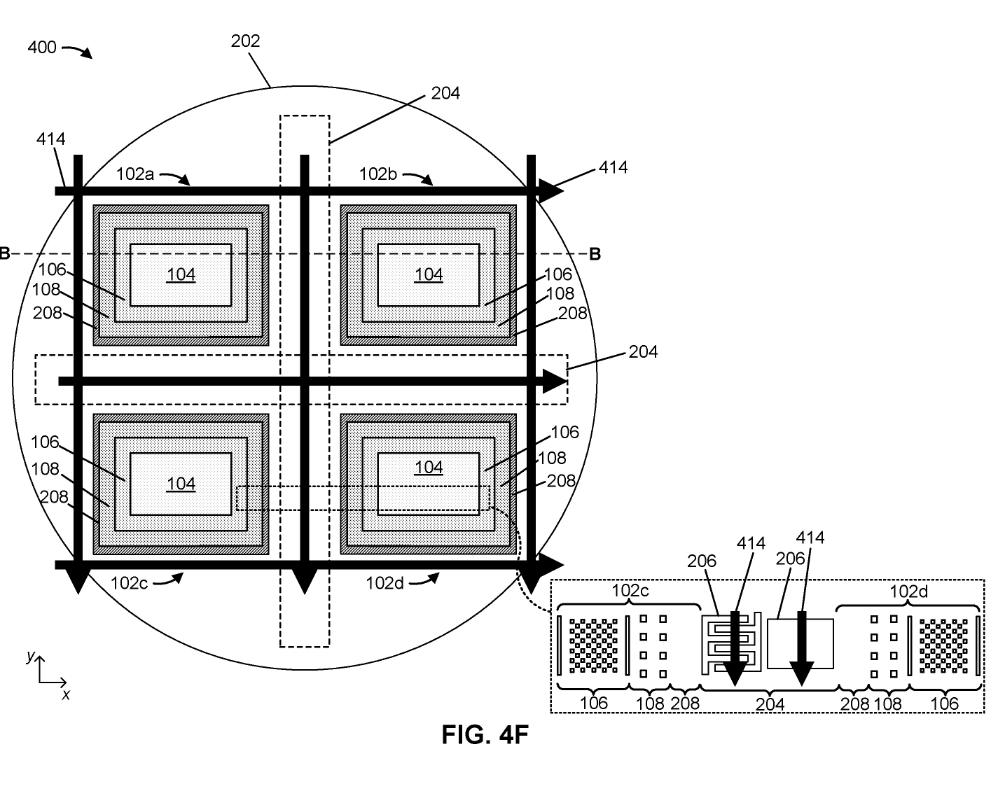

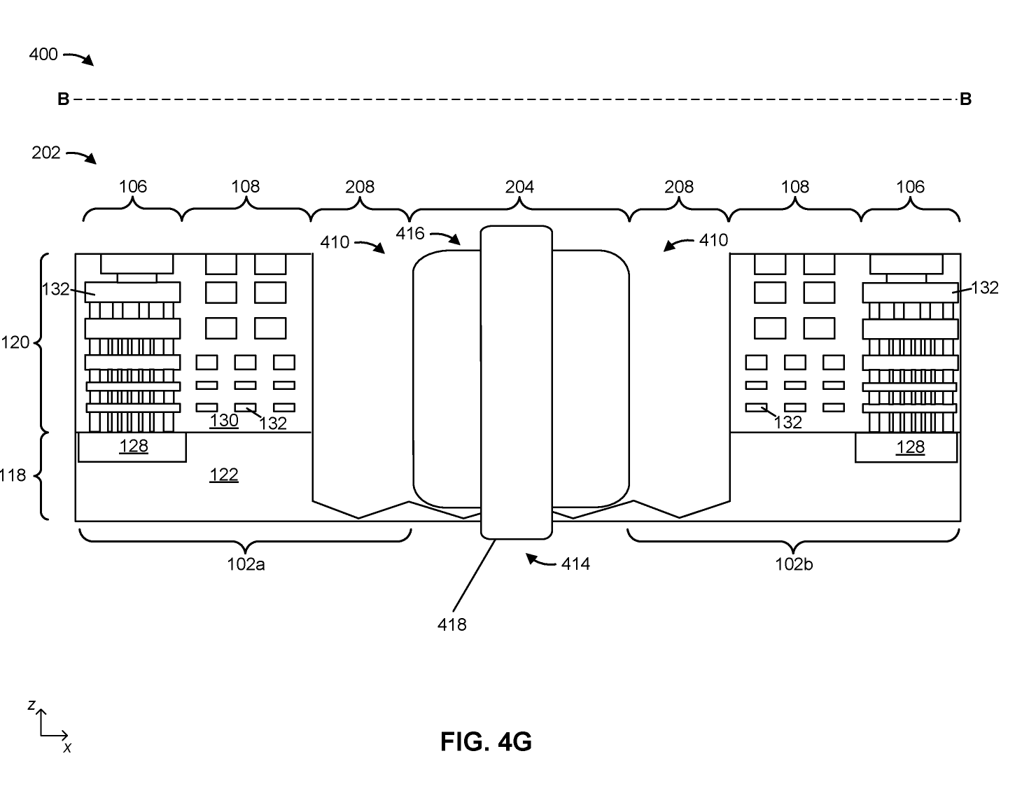

As further shown in FIG. 2A, a buffer region 108 may have a lateral width (indicated in FIG. 2A as a dimension D1) that is in a direction that is approximately perpendicular to the length of the buffer region 108. A buffer region 208 may have a lateral width (indicated in FIG. 2A as a dimension D2) that is in a direction that is approximately perpendicular to the length of the buffer region 208. In some implementations, the lateral widths of the buffer regions 108 and 208 may be approximately equal prior to singulation of the semiconductor devices 102a-102d from the wafer 202. However, and as described in connection with FIGS. 4A-4F, 5A-5G, 7A-7F, and/or elsewhere herein, grooves may be formed through the buffer regions 208 of the semiconductor devices 102a-102d during a process to cut or singulate the semiconductor devices 102a-102d from the wafer 202. Therefore, one or more segments of the buffer regions 208 of the semiconductor devices 102a-102d may have a lesser lateral width than the lateral width of the buffer regions 108 after the process to cut or singulate the semiconductor devices 102a-102d from the wafer 202. In some implementations, prior to singulation, the buffer regions 108 and 208 may each have a lateral width that is included in a range of approximately 50 microns to approximately 100 microns to provide an effective buffer for the device regions 104 of the semiconductor devices 102a-102d from heat and mechanical stresses generated during the die singulation process. However, other values and ranges are within the scope of the present disclosure.

As shown in FIG. 2B, a buffer region 208 of a semiconductor device 102 (e.g., the semiconductor device 102c, the semiconductor device 102d) may include a portion of the dielectric region 130 of the semiconductor device 102. In some implementations, the buffer region 208 of a semiconductor device 102 (e.g., the semiconductor device 102c, the semiconductor device 102d) may include one or more metallization structures 132 in the portion of the dielectric region 130. In some implementations, the buffer region 208 of a semiconductor device 102 (e.g., the semiconductor device 102c, the semiconductor device 102d) the portion of the dielectric region 130 is free of metallization structures 132.

As indicated above, FIGS. 2A and 2B are provided as an example. Other examples may differ from what is described with regard to FIGS. 2A and 2B.

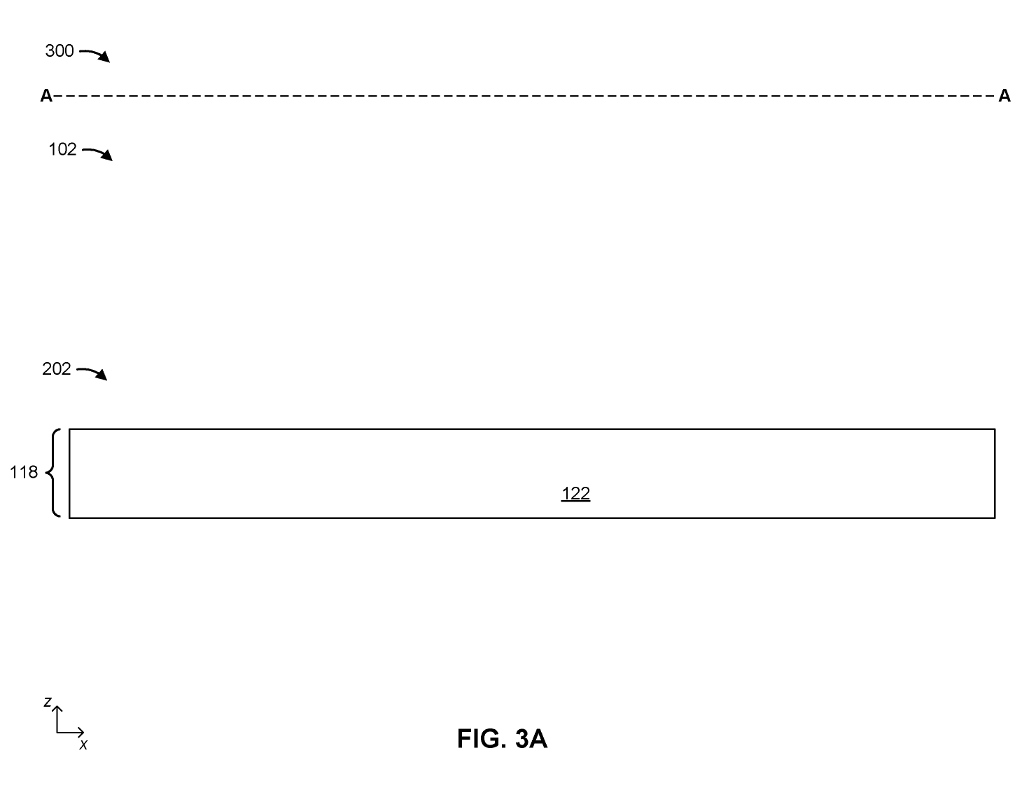

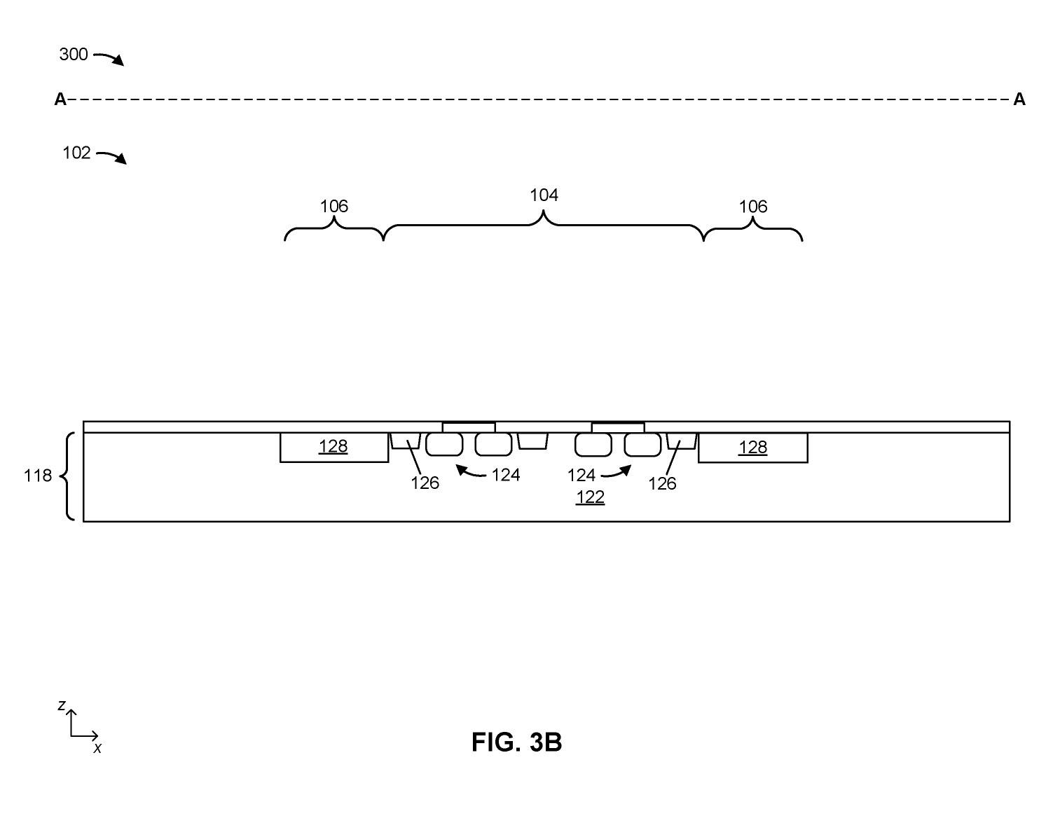

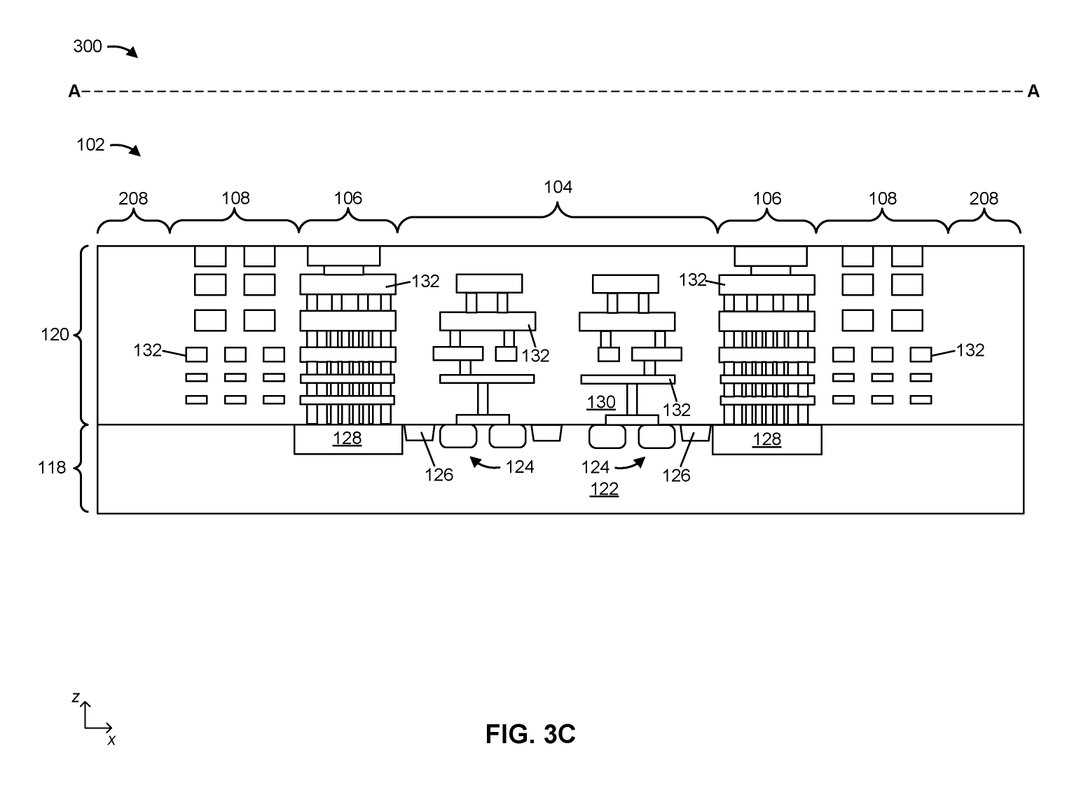

FIGS. 3A-3C are diagrams of an example implementation 300 of forming the semiconductor devices 102 on a wafer 202 described herein. In some implementations, one or more semiconductor processing tools, such as a deposition tool, an exposure tool, a developer tool, an etch tool, an ion implantation tool, a bonding tool, a planarization tool, and/or another type of semiconductor processing tool, may be used to perform one or more operations described in connection with FIGS. 3A-3C.

As shown in FIG. 3A, the wafer 202 may be provided. The wafer 202 may be provided in the form of a semiconductor wafer, an SOI wafer, a dielectric wafer (e.g., a glass wafer), and/or another type of work piece. A portion of the wafer 202 may correspond to the substrate layer 122 of the semiconductor device 102 in which the device layer 118 of the semiconductor device 102 is formed.

As shown in FIG. 3B, the integrated circuit devices 124 of the device region 104 of the semiconductor device 102 may be formed in and/or on the substrate layer 122 in the device layer 118 of the semiconductor device 102. One or more semiconductor processing tools may be used to form one or more portions of the integrated circuit devices 124. For example, an ion implantation tool may be used to dope one or more regions in the substrate layer 122 with one or more types of dopants to form well regions, implant regions, and/or other types of doped regions in the substrate layer 122 for the integrated circuit devices 124. As another example, a deposition tool may be used to perform various deposition operations to deposit layers and/or structures of the integrated circuit devices 124, and/or to deposit photoresist layers for etching the substrate layer 122 and/or portions of the deposited layers. As another example, an exposure tool may be used to expose the photoresist layers to form patterns in the photoresist layers. As another example, a developer tool may be used to develop the patterns in the photoresist layers. As another example, an etch tool may be used to etch the substrate layer 122 and/or portions of the deposited layers to form the integrated circuit devices 124. As another example, a planarization tool may be used to planarize portions of the integrated circuit devices 124. As another example, a plating tool may be used to deposit metal structures and/or layers of the integrated circuit devices 124.

As further shown in FIG. 3B, one or more isolation regions 126 may be formed in the substrate layer 122 in the device region 104 of the semiconductor device 102. Additionally and/or alternatively, one or more isolation regions 128 may be formed in the substrate layer 122 in the seal ring region 106 of the semiconductor device 102. In some implementations, forming the isolation region(s) 126 and/or the isolation region(s) 128 may include etching the substrate layer 122 (e.g., using an etch tool) to form recesses in the substrate layer 122 and depositing dielectric material (e.g., using a deposition tool) in the recesses. In some implementations, forming the isolation region(s) 126 and/or the isolation region(s) 128 may include implanting dopants (e.g., using an ion implantation tool) in the substrate layer 122.

As shown in FIG. 3C, the interconnect layer 120 of the semiconductor device 102 may be formed above the device layer 118 of the semiconductor device 102. To form the interconnect layer 120, one or more dielectric layers of the dielectric region 130 may be deposited, and a layer of metallization structures 132 may be formed in the one or more dielectric layers.

A deposition tool may be used to deposit the one or more dielectric layers using a physical vapor deposition (PVD) technique, an atomic layer deposition (ALD) technique, a chemical vapor deposition (CVD) technique, an oxidation technique, and/or another suitable deposition technique. The one or more dielectric layers may be deposited in one or more deposition operations. In some implementations, a planarization tool may be used to perform a planarization operation (e.g., a chemical-mechanical planarization (CMP) operation) to planarize the one or more dielectric layers after the one or more dielectric layers are deposited.

In some implementations, a pattern in a photoresist layer is used to etch the dielectric layer(s) to form recesses in the dielectric layer(s). In these implementations, a deposition tool may be used to form the photoresist layer on the dielectric layer(s) (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dielectric layer(s) based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer(s) based on a pattern.

A deposition tool may be used to deposit the electrically conductive material of the first layer of metallization structures 132 using a CVD technique, a PVD technique, an ALD technique, an electroplating technique, and/or another suitable deposition technique. The first layer of metallization structures 132 may be deposited in the device region 104, in the seal ring region 106, and/or in the buffer region 108. In some implementations, one or more metallization structures 132 of the first layer of metallization structures 132 may be deposited in the buffer region 208. The first layer of metallization structures 132 may be deposited in one or more deposition operations. In some implementations, a seed layer is first deposited, and the first layer of metallization structures 132 is deposited on the seed layer. In some implementations, a planarization tool is used to perform a planarization operation (e.g., a CMP operation) to planarize the first layer of metallization structures 132 after the first layer of metallization structures 132 is deposited.

Subsequent layers of metallization structures 132 may be formed in a similar manner in the device region 104, in the seal ring region 106, and/or in the buffer region 108. In some implementations, one or more layers metallization structures 132 may be deposited in the buffer region 208. Alternatively, the portion of the dielectric region 130 in the buffer region 208 may be manufactured to be free of metallization structures 132.

As indicated above, FIGS. 3A-3C are provided as an example. Other examples may differ from what is described with regard to FIGS. 3A-3C.

FIGS. 4A-4G are diagrams of an example implementation 400 of a die singulation process for singulating semiconductor devices 102 from a wafer 202 described herein. One or more of the operations described in connection with FIGS. 4A-4G may be performed using one or more semiconductor processing tools, such as a wafer/die transport tool, a laser grooving tool, a wafer sawing tool, and/or another semiconductor processing tool.

As shown in FIG. 4A, semiconductor devices 102a-102d may be formed on a wafer 202. The semiconductor devices 102a-102dmay be formed on the wafer 202 in a similar manner as described in connection with FIGS. 3A-3C. The semiconductor devices 102a-102d may be manufactured to each include a device region 104, a seal ring region 106 laterally surrounding the device region 104, a buffer region 108 laterally surrounding the seal ring region 106, and another buffer region 208 laterally surrounding the buffer region 108. Moreover, the semiconductor devices 102a-102d may be manufactured such that the buffer regions 208 of the semiconductor devices 102a-102d have densities of metallization structures 132 that are less than the densities of metallization structures 132 in the buffer regions 108 of the semiconductor devices 102a-102d. In some implementations, the semiconductor devices 102a-102d may be manufactured such that the buffer regions 208 of the semiconductor devices 102a-102d are free of metallization structures 132.

As further shown in FIG. 4A, the semiconductor devices 102a-102d may be formed on the wafer 202 such that the semiconductor devices 102a-102d are spaced apart by scribe line regions 204 laterally between the semiconductor devices 102a-102d. In some implementations, test structures 206, dummy structures 208, and/or other structures that contain metallization structures 132 may be formed in one or more of the scribe line regions 204 and used for monitoring the manufacturing processes for the wafer 202 and/or the semiconductor devices 102a-102d manufactured thereon.

While FIG. 4A illustrates the semiconductor devices 102a-102d being formed in a grid layout, and the scribe line regions 204 having a similar overall grid layout, the semiconductor devices 102a-102d and the associated scribe line regions 204 between them may have another layout.

As shown in FIGS. 4B and 4C, a first laser grooving operation may be performed for the wafer 202 as part of the die singulation process. The first laser grooving operation includes forming grooves (e.g., narrow grooves) on opposing sides of the scribe line regions 204. The grooves may be formed in and/or through the buffer regions 208 of the semiconductor devices 102a-102d so that the grooves are located between the buffer regions 108 and the scribe line regions 204.

FIG. 4B illustrates groove paths 402 for forming the grooves. A laser grooving tool may be used to form the grooves, where the laser grooving tool emits a laser beam that is moved along the groove paths 402 to form the grooves. Thus, the grooves may cross over one or more scribe line regions 204 between laterally adjacent semiconductor devices 102. For example, a laser beam may be moved along a groove path 402 through the buffer regions 208 of the semiconductor devices 102a and 102c, and this may result in the groove extending across the scribe line region 204 between the semiconductor devices 102a and 102c.

As shown in FIG. 4C, the groove paths 402 may cut through the portions of the dielectric region 130 in the buffer regions 208 of the semiconductor devices 102a-102d.The laser beam 404 of the laser grooving tool may also cut into a portion of the substrate layer 122 of the semiconductor devices 102a-102d. In some implementations, a lateral cutting width of the laser beam 404 is included in a range of approximately 6 microns to approximately 12 microns. However, other values and ranges are within the scope of the present disclosure.

Because the buffer regions 208 include a low density of metallization structures 132 (or are free of metallization structures 132), heat and vibration generated from the laser beam 404 cutting through the dielectric region 130 is primarily contained within the dielectric region 130 and does not propagate (or minimally propagates) into the metallization structures 132 of the semiconductor devices 102a-102d. This reduces and/or minimizes the likelihood of cracking, delamination, and/or other types of physical damage in the device regions 104 of the semiconductor devices 102a-102d.

As shown in FIGS. 4D and 4E, a second laser grooving operation may be performed for the wafer 202 as part of the die singulation process. The second laser grooving operation includes forming grooves (e.g., wide grooves) in the scribe line regions 204 of the wafer 202.

FIG. 4D illustrates groove paths 408 for forming the grooves. A laser grooving tool may be used to form the grooves, where the laser grooving tool emits a laser beam that is moved along the groove paths 408 to form the grooves.

As shown in FIG. 4E, the groove paths 408 may cut through the portions of the dielectric region 130 in the scribe line regions 204 between the semiconductor devices 102a-102d. The groove paths 408 may be located laterally between grooves 410 that were formed in and/or through the buffer regions 208 of the semiconductor devices 102a-102d. The grooves 410 formed in the buffer regions 208 of the semiconductor devices 102a-102d may isolate the semiconductor devices 102a-102d from the head and/or mechanical disturbances (e.g., vibration) generated during formation of the grooves through the scribe line regions 204.

The laser beam 412 of the laser grooving tool may cut into a portion of the substrate layer 122 of the semiconductor devices 102a-102d. In some implementations, a lateral cutting width of the laser beam 412 is included in a range of approximately 40 microns to approximately 50 microns. However, other values and ranges are within the scope of the present disclosure.

As shown in FIGS. 4F and 4G, a wafer sawing tool may be used to cut through the remaining portions substrate layer 122 in the scribe line regions 204 to fully singulate the semiconductor devices 102a-102d from the wafer 202. As shown in FIG. 4F, the cutting paths 414 for the wafer sawing tool may be through the scribe line regions 204 laterally between the semiconductor devices 102a-102d.

As shown in FIG. 4G, the cutting paths 414 for the wafer sawing tool may be through the grooves 416 formed in the second laser grooving operation. A saw blade 418 may be passed through the grooves 416 along the cutting paths 414 to cut through the remaining portions of the substrate layer 122 in the scribe line regions 204.

As indicated above, FIGS. 4A-4G are provided as an example. Other examples may differ from what is described with regard to FIGS. 4A-4G.

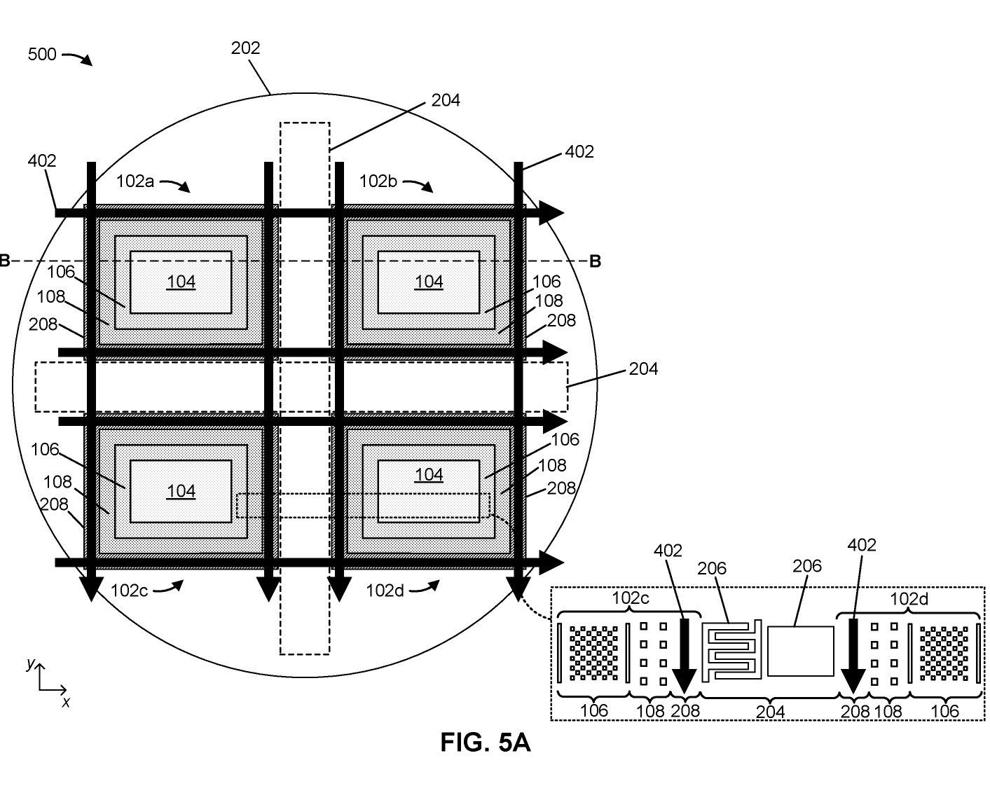

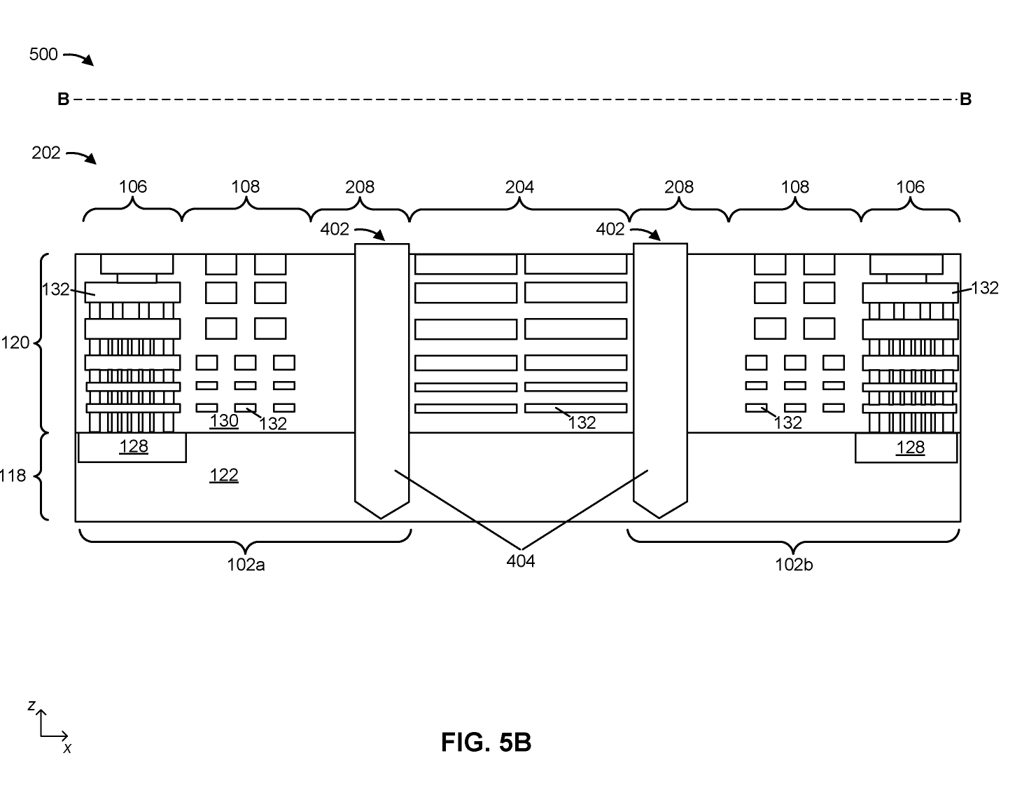

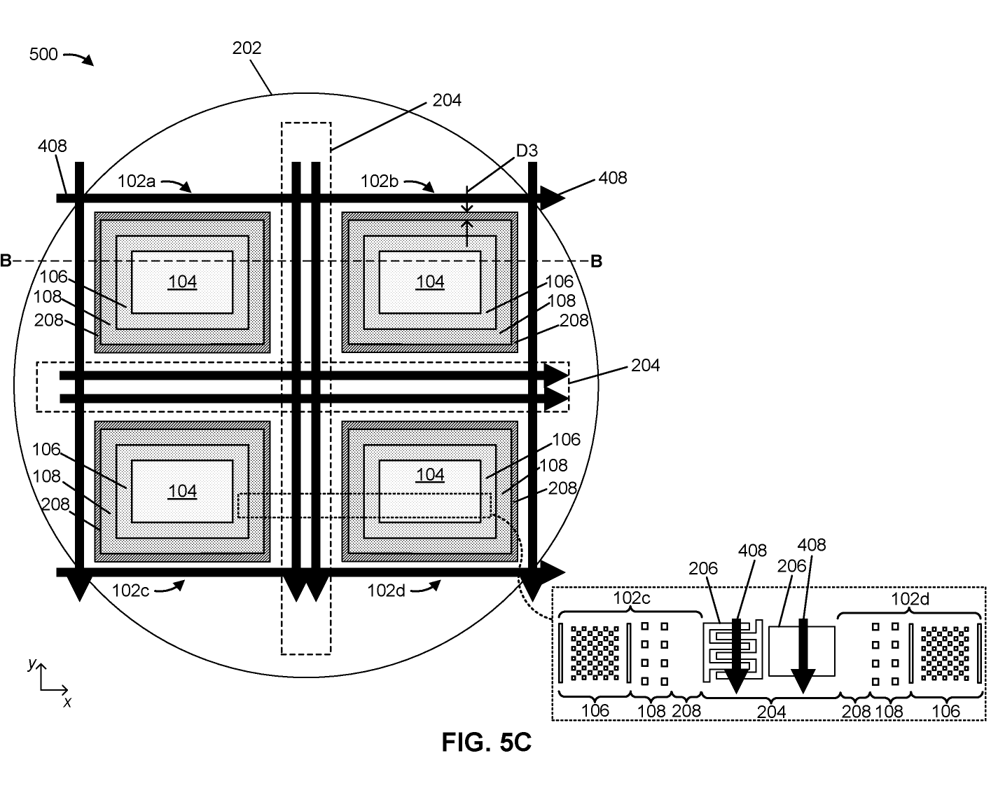

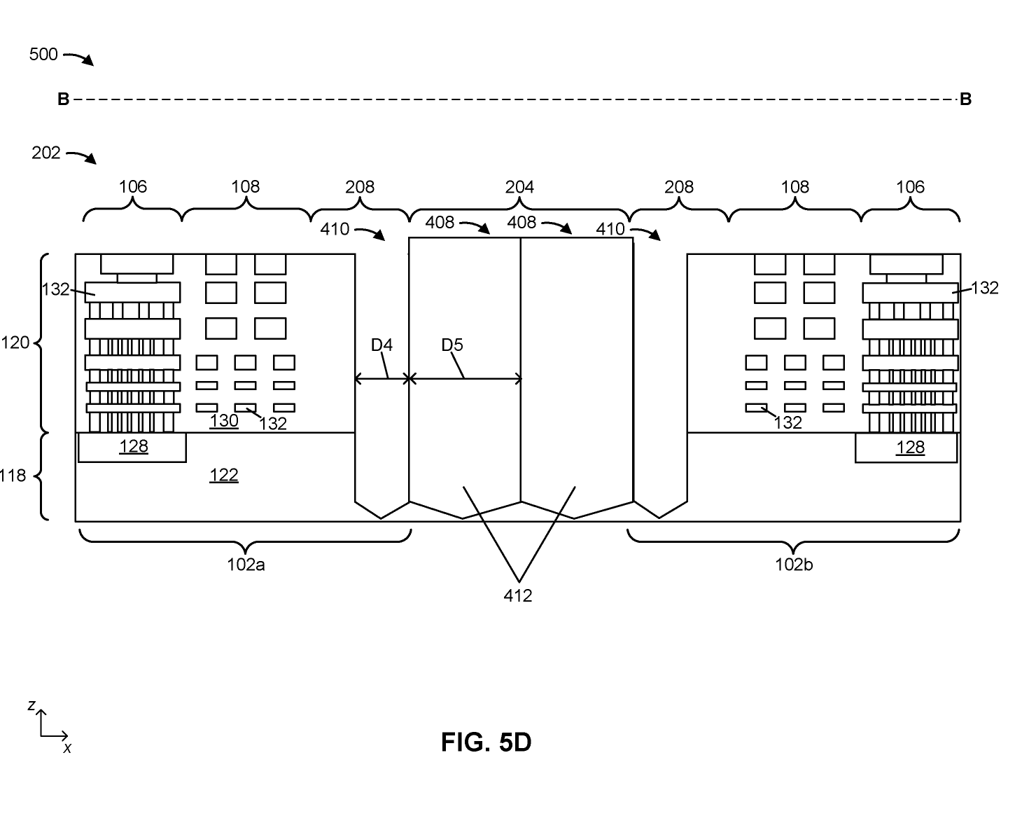

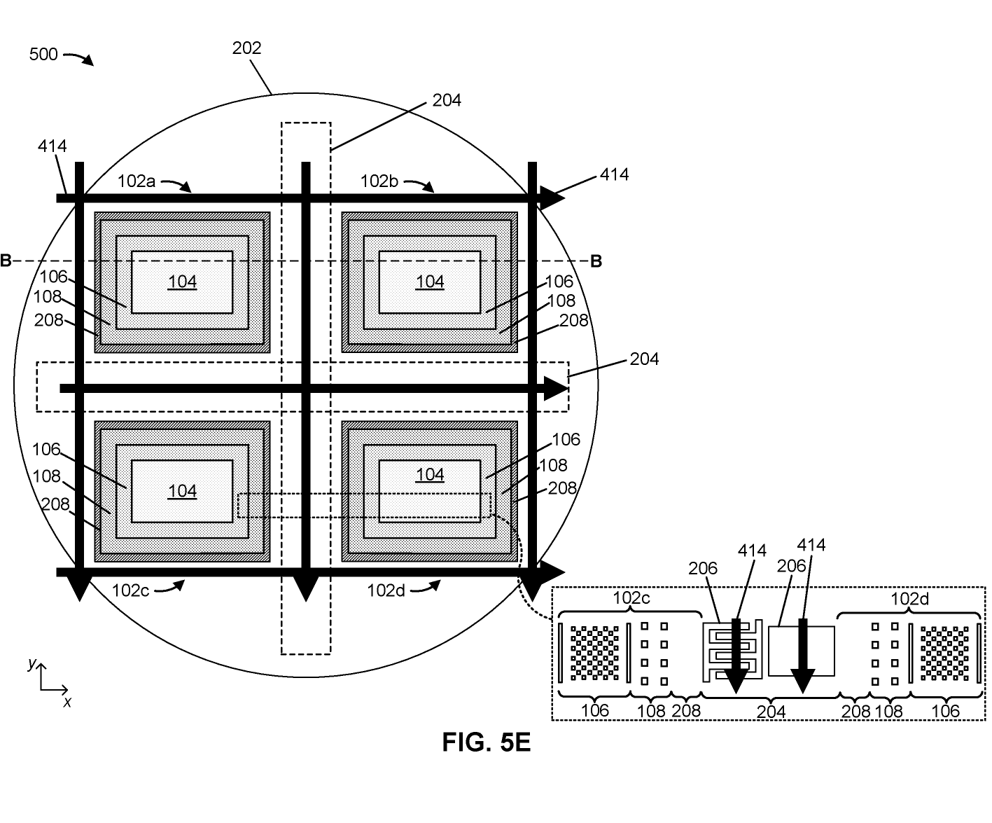

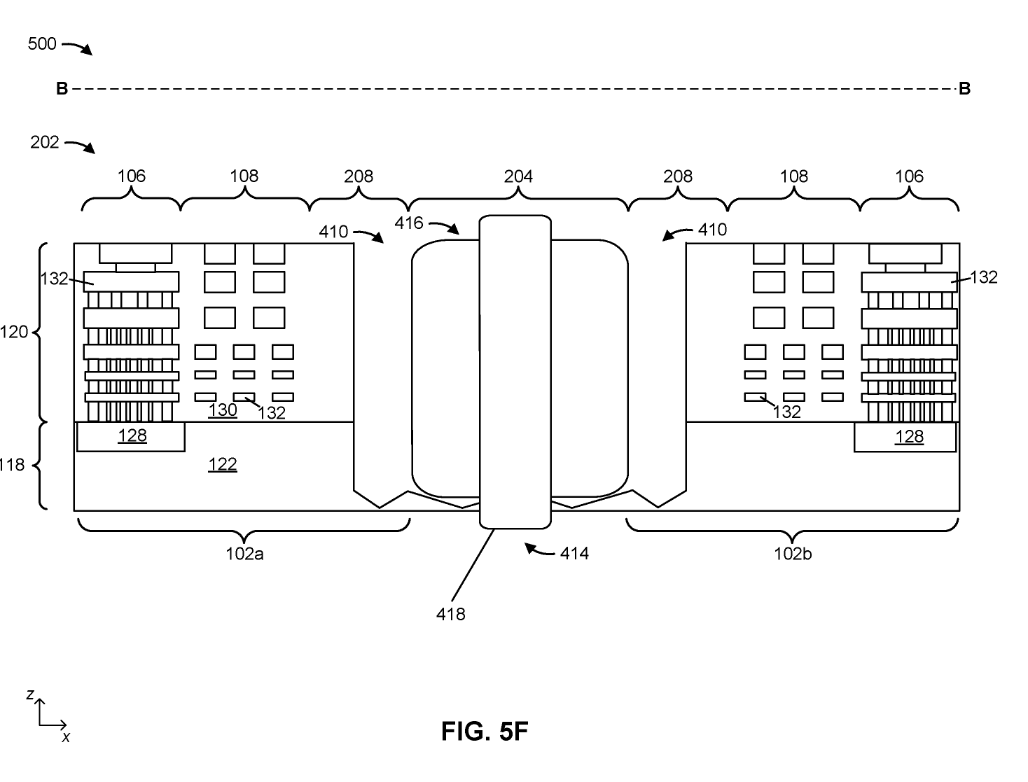

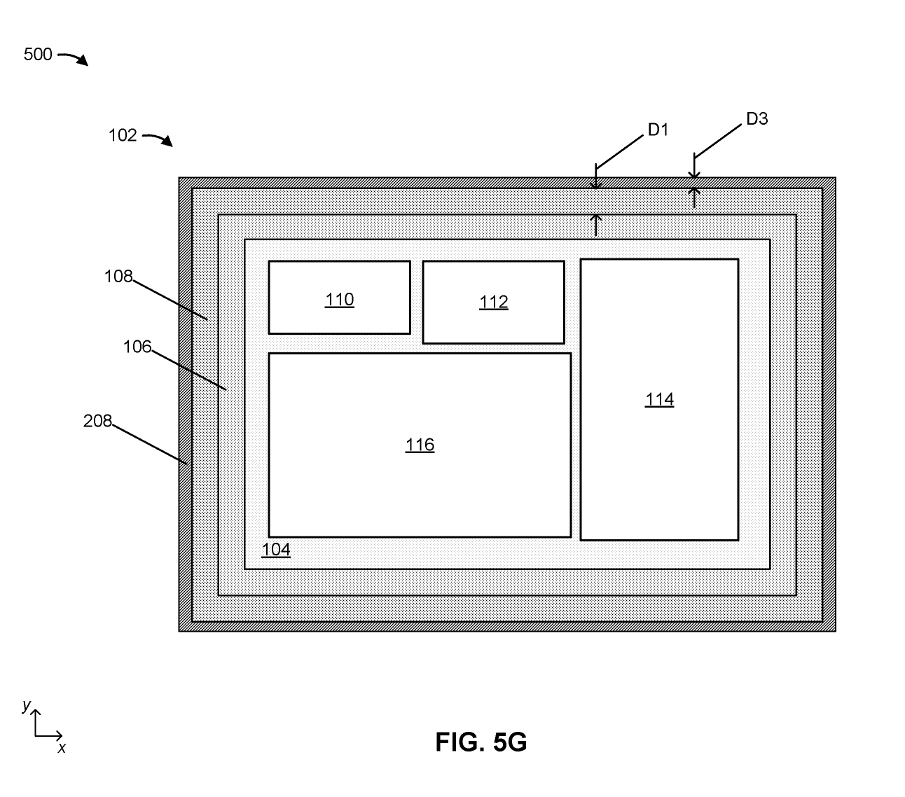

FIGS. 5A-5G are diagrams of an example implementation 500 of a die singulation process for singulating semiconductor devices 102 from a wafer 202 described herein. One or more of the operations described in connection with FIGS. 5A-5G may be performed using one or more semiconductor processing tools, such as a wafer/die transport tool, a laser grooving tool, a wafer sawing tool, and/or another semiconductor processing tool.

As shown in FIGS. 5A-5F, the example implementation 500 of the die singulation process is similar to the example implementation 400 of the die singulation process illustrated in FIGS. 4A-4G. However, in the example implementation 500 of the die singulation process, the buffer region 208 is not fully removed from the semiconductor devices 102a-102d.

As shown in FIG. 5D, the lateral widths of the grooves 410 formed through the buffer regions 208 of the semiconductor devices 102a-102d (indicated in FIG. 4D as a dimension D4) is less than the lateral widths of the buffer regions 208, resulting in less than the entireties of the portions of the dielectric regions 130 being removed from the buffer regions 208. The lateral widths of the grooves 410 formed through the buffer regions 208 are less than the lateral widths of the grooves formed through the scribe line regions 204 (indicated in FIG. 5D as a dimension D5).

As shown in FIG. 5G, the a resulting semiconductor device 102 singulated from the wafer 202 includes a portion of the buffer region 208. The remaining portion of the buffer region 208 may be included around the buffer region 108. In other words, the remining portion of the buffer region 208 may be included on four (4) sides of the semiconductor device 102.

The lateral width of the remaining portion of the buffer region 208 (indicated in FIG. 5G as a dimension D3) may be less than the lateral width of the buffer region 108 (dimension D1). In some implementations, the width of the remaining portion of the buffer region 208 may be included in a range of approximately 3 microns and approximately 50 microns. However, other values and ranges are within the scope of the present disclosure.

As indicated above, FIGS. 5A-5G are provided as an example. Other examples may differ from what is described with regard to FIGS. 5A-5G.

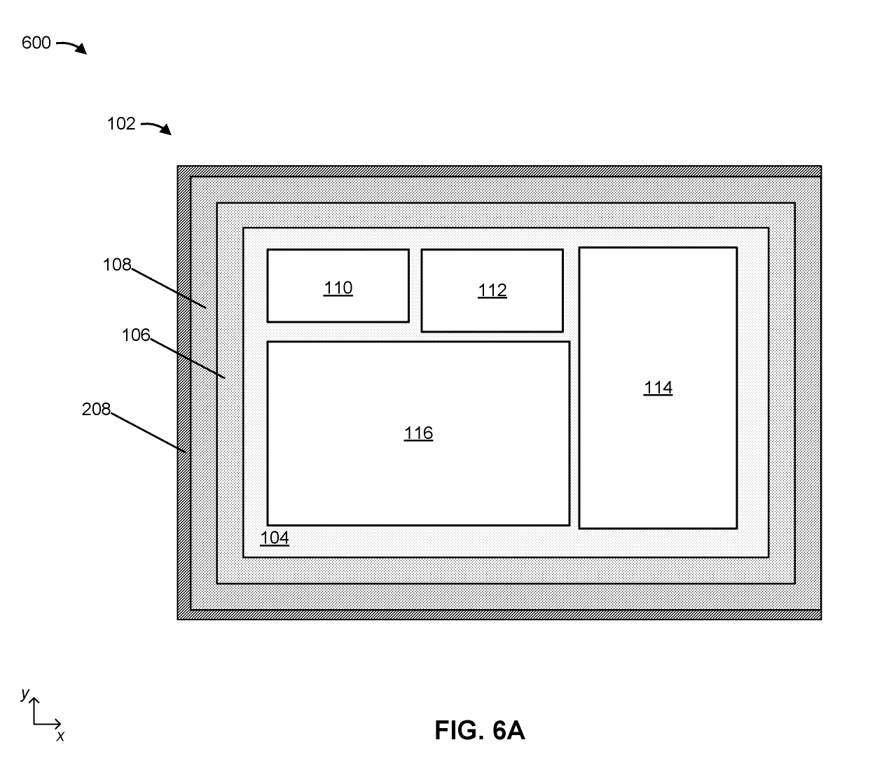

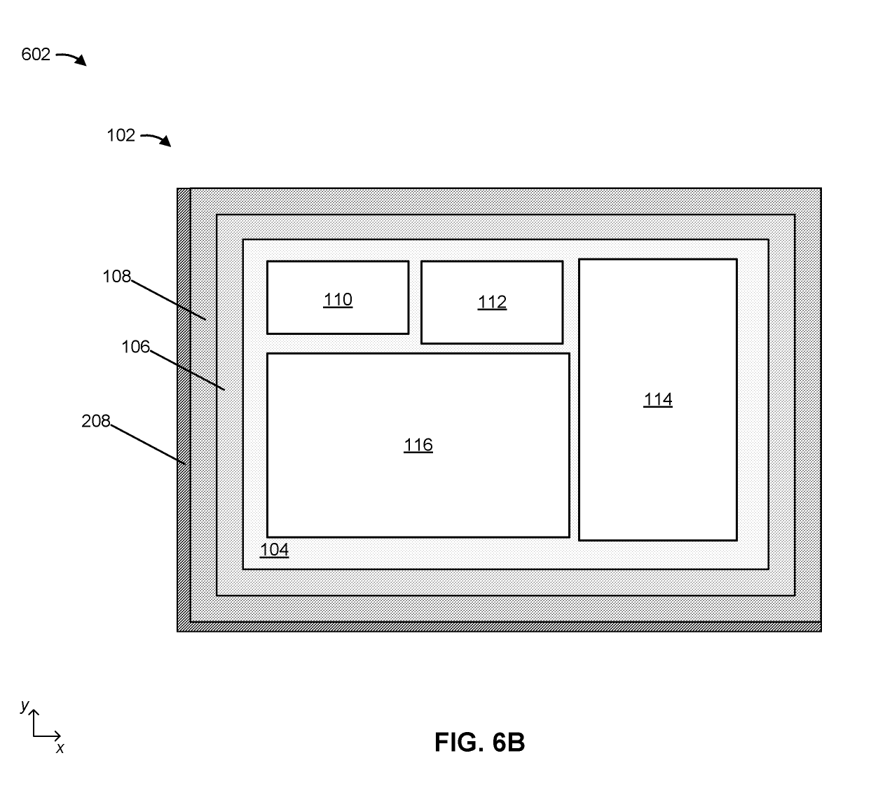

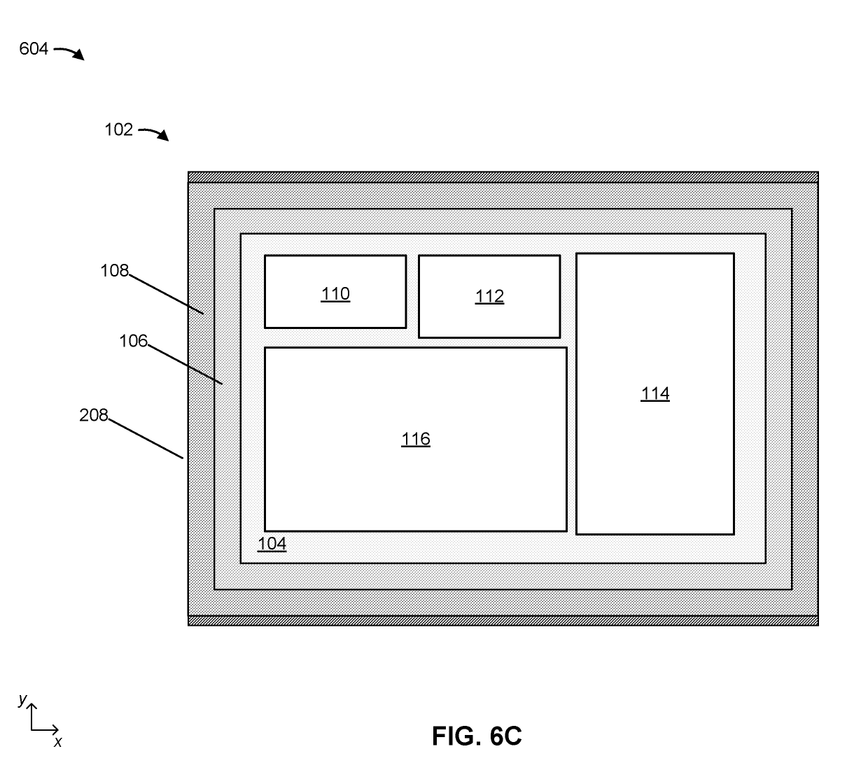

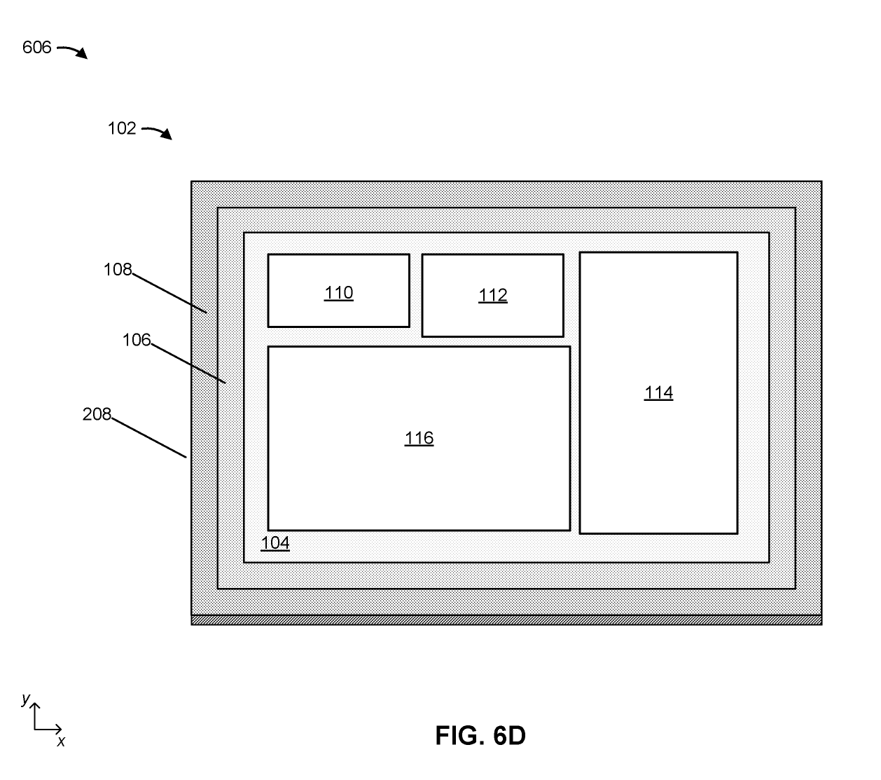

FIGS. 6A-6D are diagrams of examples of semiconductor devices 102 singulated from a wafer 202 described herein. The semiconductor devices 102 may be singulated from a wafer 202 by processes described in connection with FIGS. 4A-4G, 5A-5G, and/or elsewhere herein.

FIG. 6A illustrates an example 600 of a semiconductor device 102 singulated from a wafer 202. As shown in FIG. 6A, grooves 410 may be formed through a segment of the buffer region 208 of the semiconductor device 102 such that the segment of the buffer region 208 is removed from the semiconductor device 102. The resulting semiconductor device 102 after the die singulation process includes three remaining segments of the buffer regions 208 that are concatenated together at ends of the three remaining segments of the buffer region 208. The three remaining segments may be located on three sides of the semiconductor device 102.

FIG. 6B illustrates an example 602 of a semiconductor device 102 singulated from a wafer 202. As shown in FIG. 6B, grooves 410 may be formed through two segments of the buffer region 208 of the semiconductor device 102 such that the segments of the buffer region 208 are removed from the semiconductor device 102. The resulting semiconductor device 102 after the die singulation process includes two remaining segments of the buffer regions 208 on two adjacent sides of the semiconductor device 102.

FIG. 6C illustrates an example 604 of a semiconductor device 102 singulated from a wafer 202. As shown in FIG. 6C, grooves 410 may be formed through two segments of the buffer region 208 of the semiconductor device 102 such that the segments of the buffer region 208 are removed from the semiconductor device 102. The resulting semiconductor device 102 after the die singulation process includes two remaining segments of the buffer regions 208 on two opposing sides of the semiconductor device 102.

FIG. 6D illustrates an example 606 of a semiconductor device 102 singulated from a wafer 202. As shown in FIG. 6D, grooves 410 may be formed through three segments of the buffer region 208 of the semiconductor device 102 such that the segments of the buffer region 208 are removed from the semiconductor device 102. The resulting semiconductor device 102 after the die singulation process includes a single segment of the buffer regions 208 on one side of the semiconductor device 102.

As indicated above, FIGS. 6A-6D are provided as examples. Other examples may differ from what is described with regard to FIGS. 6A-6D.

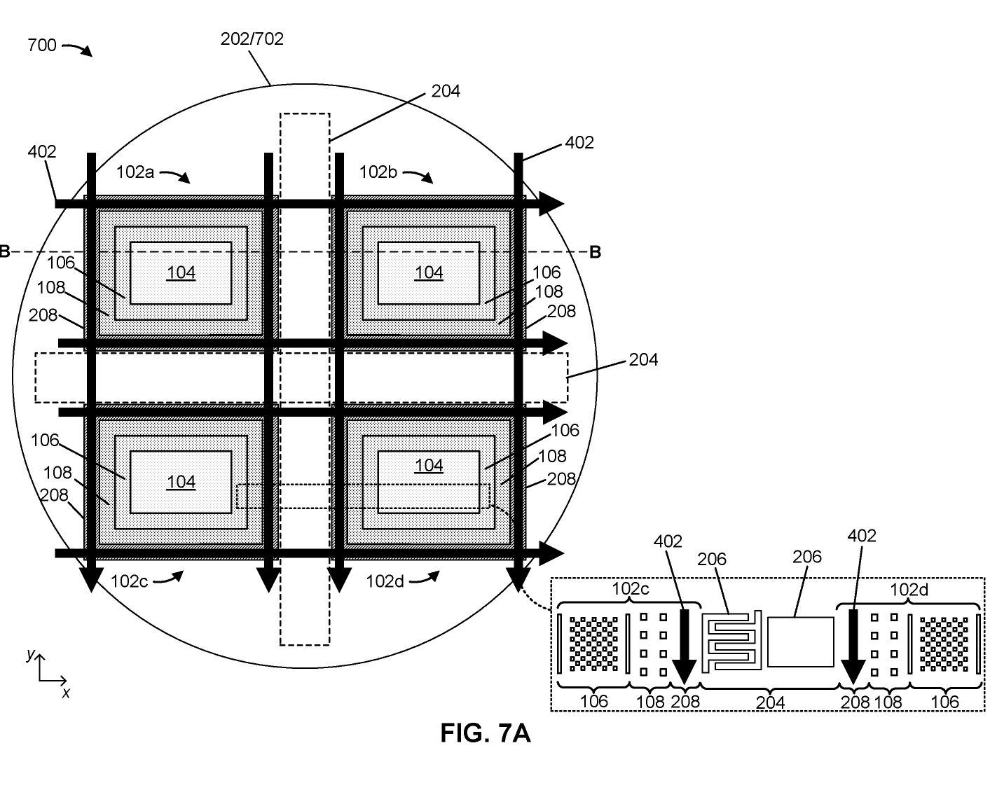

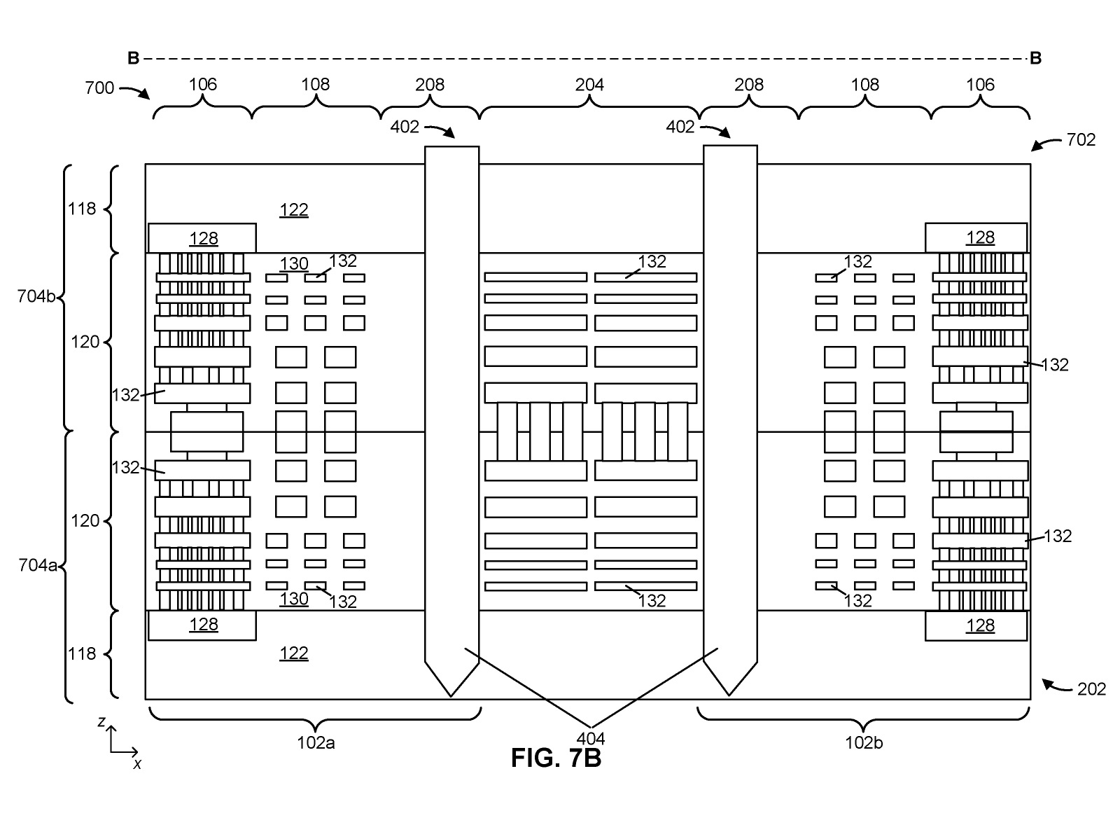

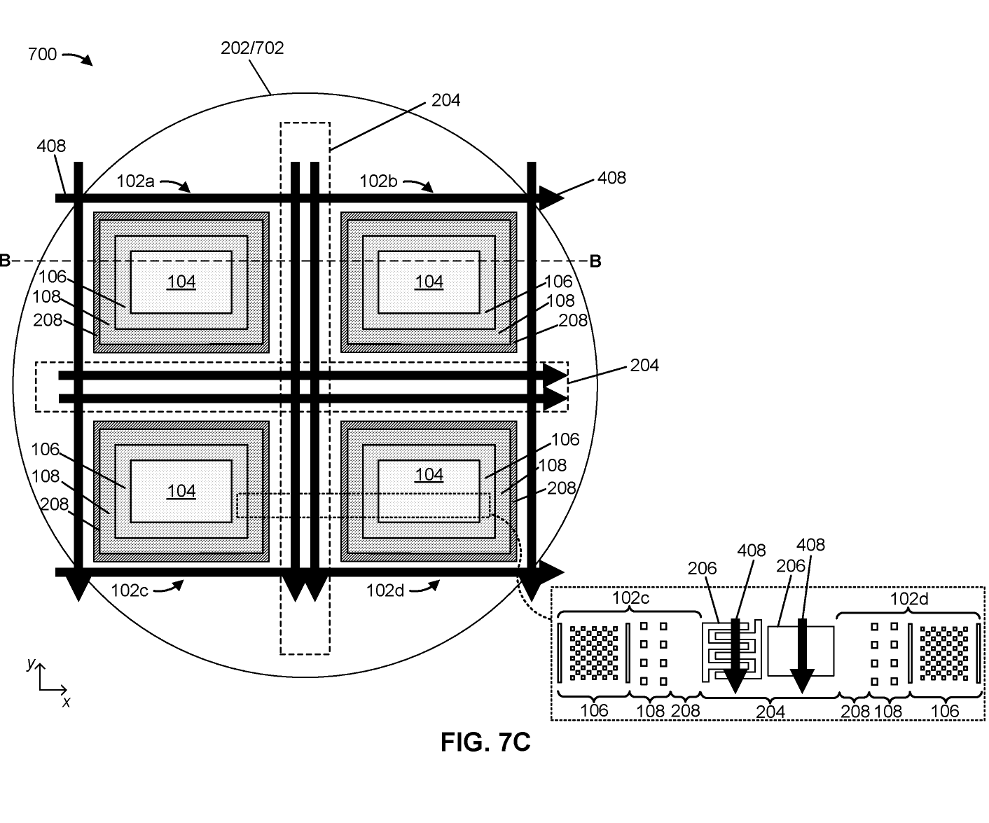

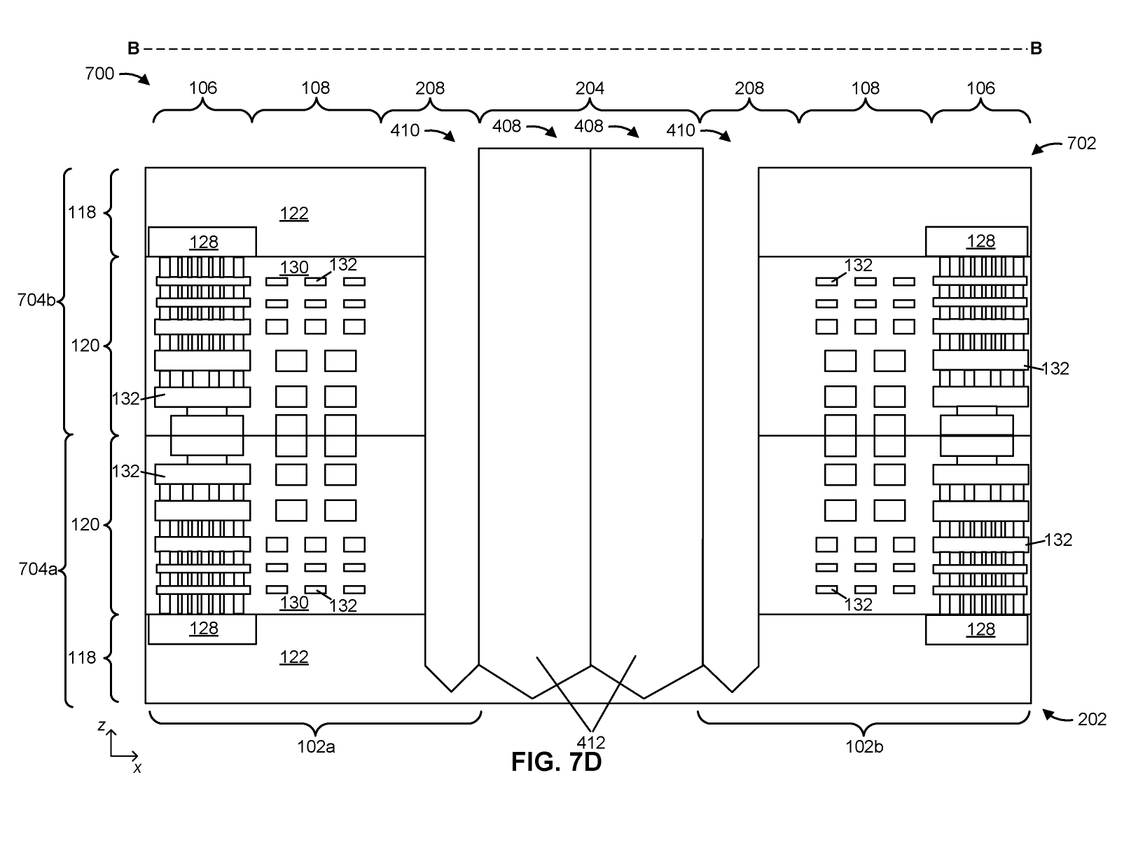

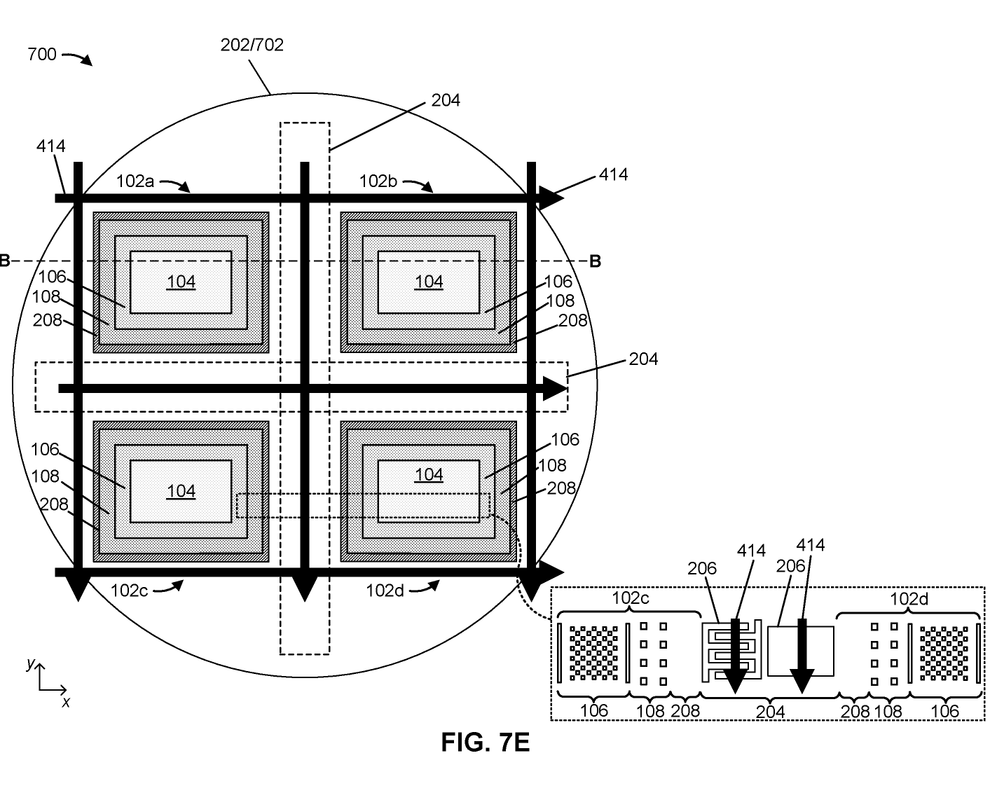

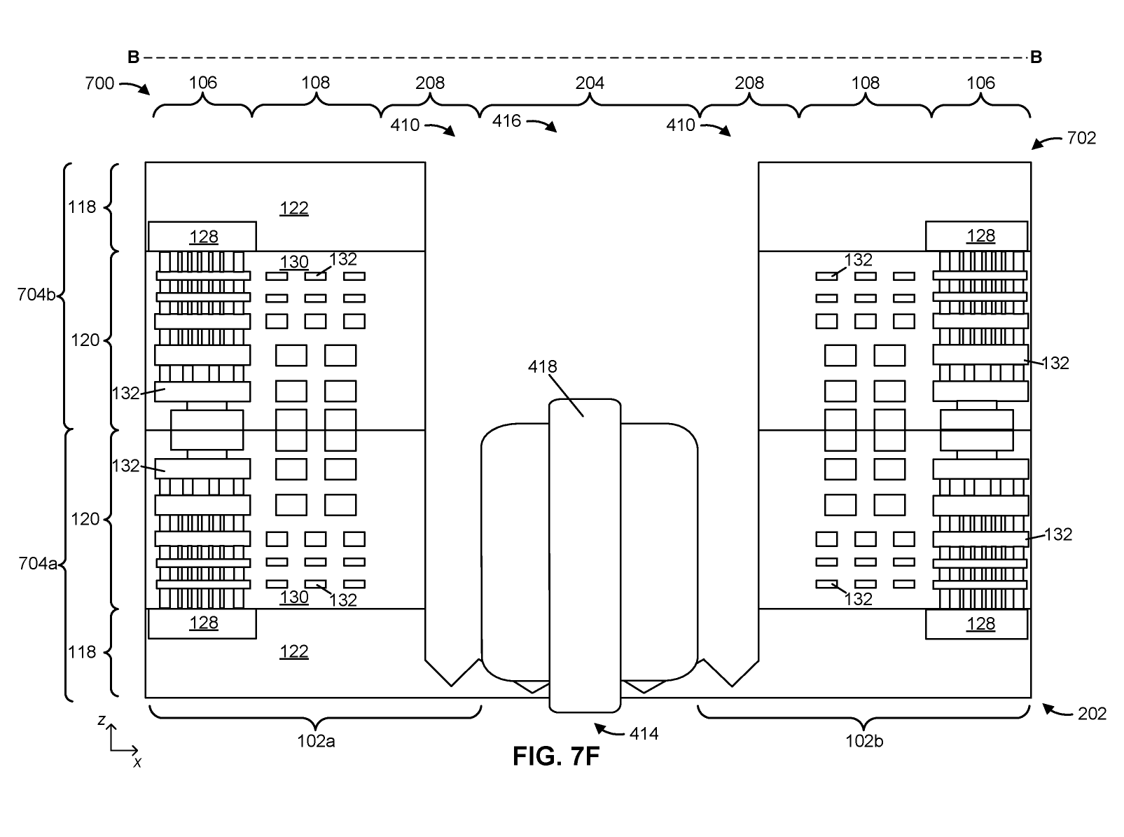

FIGS. 7A-7F are diagrams of an example implementation 700 of a die singulation process for singulating semiconductor devices 102 from a wafer stack described herein. One or more of the operations described in connection with FIGS. 7A-7F may be performed using one or more semiconductor processing tools, such as a wafer/die transport tool, a laser grooving tool, a wafer sawing tool, and/or another semiconductor processing tool.

As shown in FIGS. 7A-7F, the example implementation 700 of the die singulation process is similar to the example implementation 500 of the die singulation process illustrated in FIGS. 5A-5G. However, in the example implementation 700 of the die singulation process, the wafer 202 is bonded with another wafer 702 to form a wafer stack, and the semiconductor devices 102a-102d are singulated from the wafer stack by the die singulation process.

As shown in FIG. 7B, a semiconductor device 102 (e.g., a semiconductor device 102a) may be formed by bonding a semiconductor die 704a and another semiconductor die 704b such that the semiconductor dies 704a and 704b are stacked and vertically arranged in the semiconductor device 102. The semiconductor die 704a may be formed on the wafer 202 according to the operations described in connection with FIGS. 3A-3C, and the semiconductor die 704b may be formed on the wafer 702 according to the operations described in connection with FIGS. 3A-3C. The wafers 202 and 702 may be bonded together such that dielectric-to-dielectric bonds are formed between the dielectric regions 130 of the semiconductor dies 704a and 704b, and such that metal-to-metal bonds are formed between metallization structures 132 of the semiconductor dies 704a and 704b.

A device region 104 of a semiconductor device 102 (e.g., the semiconductor device 102a) may be laterally surrounded by a seal ring region 106 that extends through the semiconductor dies 704a and 704b. A buffer region 108 of the semiconductor device 102 may extend through the semiconductor dies 704a and 704b and may laterally surround the seal ring region 106, and another buffer region 208 of the semiconductor device 102 may extend through the semiconductor dies 704a and 704b and laterally surround the buffer region 108.

As shown in FIG. 7D, the grooves 410 formed in the buffer regions 208 of the semiconductor devices 102a-102d may extend through the semiconductor dies 704b of the semiconductor devices 102a-102d and into the semiconductor dies 704a of the semiconductor devices 102a-102d.

As shown in FIG. 7F, the grooves 416 formed in the scribe line regions 204 of the wafer stacks may extend through the semiconductor dies 704b of the semiconductor devices 102a-102d and into the semiconductor dies 704a of the semiconductor devices 102a-102d. As further shown in FIG. 7F, the saw blade 418 may be passed through the grooves 416 through the remaining portions of the substrate layer 122 of the wafer 202.

As indicated above, FIGS. 7A-7F are provided as an example. Other examples may differ from what is described with regard to FIGS. 7A-7F.

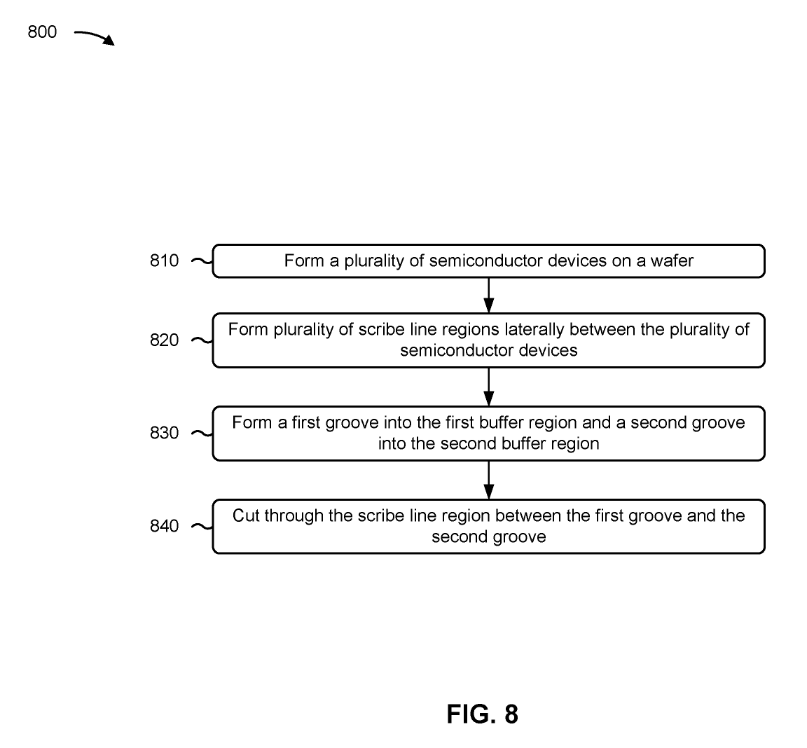

FIG. 8 is a flowchart of an example process 800 associated with forming a plurality of semiconductor devices on a wafer described herein. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a wafer/die transport tool, a laser grooving tool, a wafer cutting tool, and/or another type of semiconductor processing tool.

As shown in FIG. 8, process 800 may include forming a plurality of semiconductor devices on a wafer (block 810). For example, one or more semiconductor processing tools may be used to form a plurality of semiconductor devices (e.g., a semiconductor device 102, semiconductor devices 102a-102d) on a wafer (e.g., a wafer 202), as described herein. In some implementations, each of the plurality of semiconductor devices is manufactured to include a device region (e.g., a device region 104), a seal ring region (e.g., a seal ring region 106) laterally surrounding the device region, and a buffer region (e.g., a buffer region 108, a buffer region 208) laterally surrounding the seal ring region.

As further shown in FIG. 8, process 800 may include forming plurality of scribe line regions laterally between the plurality of semiconductor devices (block 820). For example, one or more semiconductor processing tools may be used to form plurality of scribe line regions (e.g., scribe line regions 204) laterally between the plurality of semiconductor devices, as described herein. In some implementations, a scribe line region of the plurality of scribe line regions is located laterally between a first buffer region (e.g., a buffer region 208) of a first semiconductor device (e.g., a semiconductor device 102c) of the plurality of semiconductor devices and a second buffer region (e.g., a buffer region 208) of a second semiconductor device (e.g., a semiconductor device 102d) of the plurality of semiconductor devices.

As further shown in FIG. 8, process 800 may include forming a first groove into the first buffer region and a second groove into the second buffer region (block 830). For example, one or more semiconductor processing tools may be used to form a first groove (e.g., a groove 410) into the first buffer region and a second groove (e.g., a groove 410) into the second buffer region, as described herein.

As further shown in FIG. 8, process 800 may include cutting through the scribe line region between the first groove and the second groove (block 840). For example, one or more semiconductor processing tools may be used to cut through the scribe line region between the first groove and the second groove, as described herein.

Process 800 may include additional implementations, such as any single implementation or any combination of implementations described below and/or in connection with one or more other processes described elsewhere herein.

In a first implementation, cutting through the scribe line region includes cutting through the scribe line region after forming the first groove and the second groove.

In a second implementation, alone or in combination with the first implementation, cutting through the scribe line region includes forming a third groove (e.g., a groove 416) into the scribe line region, and cutting through the third groove.

In a third implementation, alone or in combination with one or more of the first and second implementations, forming the first groove and the second groove includes performing a laser cutting operation to form the first groove and the second groove.

In a fourth implementation, alone or in combination with one or more of the first through third implementations, cutting through the scribe line region includes performing another laser cutting operation, after the laser cutting operation, to form a third groove into the scribe line region.

In a fifth implementation, alone or in combination with one or more of the first through fourth implementations, cutting through the scribe line region includes performing a sawing operation, after the other laser cutting operation, to cut through the third groove.

In a sixth implementation, alone or in combination with one or more of the first through fifth implementations, forming the plurality of semiconductor devices includes forming the first semiconductor device such that a density of metallization structures in the first buffer region is less than a density of metallization structures in a seal ring region of the first semiconductor device, and such that the density of metallization structures in the first buffer region is less than a density of metallization structures in the scribe line region.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

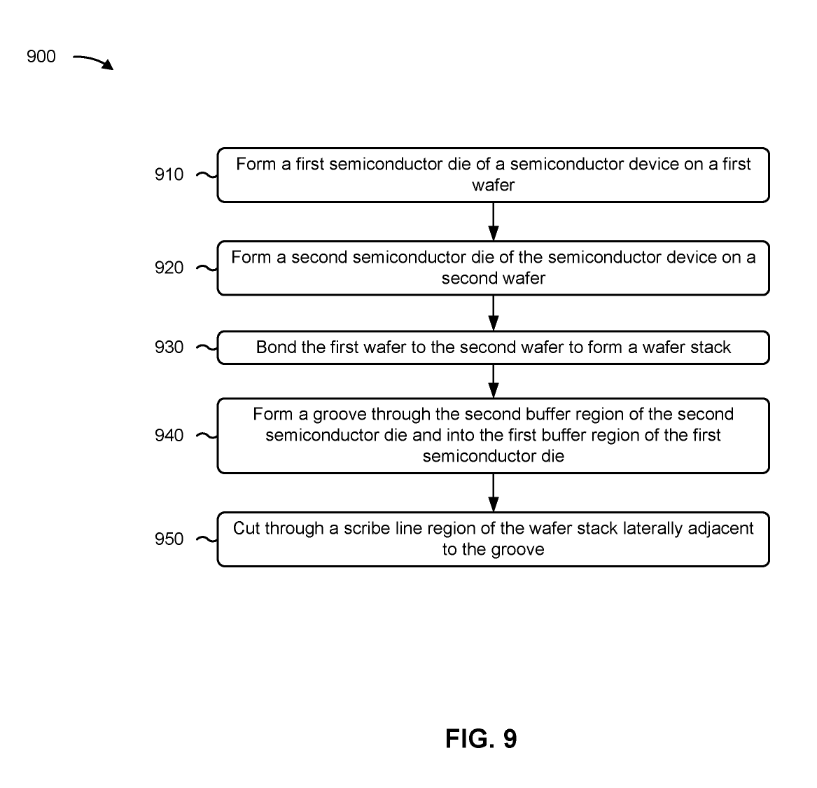

FIG. 9 is a flowchart of an example process 900 associated with forming a plurality of semiconductor devices on a substrate described herein. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a bonding tool, a wafer/die transport tool, a laser grooving tool, a wafer cutting tool, and/or another type of semiconductor processing tool.

As shown in FIG. 9, process 900 may include forming a first semiconductor die of a semiconductor device on a first substrate (block 910). For example, one or more semiconductor processing tools may be used to form a first semiconductor die (e.g., a semiconductor die 704a) of a semiconductor device (e.g., a semiconductor device 102) on a first substrate (e.g., a wafer 202), as described herein. In some implementations, the first semiconductor die is manufactured to include a first device region (e.g., a device region 104), a first seal ring region (e.g., a seal ring region 106) laterally surrounding the first device region, and a first buffer region (e.g., a buffer region 108, a buffer region 208) laterally surrounding the first seal ring region.

As further shown in FIG. 9, process 900 may include forming a second semiconductor die of the semiconductor device on a second substrate (block 920). For example, one or more semiconductor processing tools may be used to form a second semiconductor die (e.g., a semiconductor die 704b) of the semiconductor device on a second substrate (e.g., a wafer 702), as described herein. In some implementations, the second semiconductor die is manufactured to include a second device region (e.g., a device region 104), a second seal ring region (e.g., a seal ring region 106) laterally surrounding the second device region, and a second buffer region (e.g., a buffer region 108, a buffer region 208) laterally surrounding the second seal ring region.

As further shown in FIG. 9, process 900 may include bonding the first substrate to the second substrate to form a substrate stack (block 930). For example, one or more semiconductor processing tools may be used to bond the first substrate to the second substrate to form a substrate stack (e.g., a wafer stack that includes the wafers 202, 702), as described herein. In some implementations, the first semiconductor die of the semiconductor device is bonded with the second semiconductor die of the semiconductor device.

As further shown in FIG. 9, process 900 may include forming a groove through the second buffer region of the second semiconductor die and into the first buffer region of the first semiconductor die (block 940). For example, one or more semiconductor processing tools may be used to form a groove (e.g., a groove 410) through the second buffer region of the second semiconductor die and into the first buffer region of the first semiconductor die, as described herein.

As further shown in FIG. 9, process 900 may include cutting through a scribe line region of the substrate stack laterally adjacent to the groove (block 950). For example, one or more semiconductor processing tools may be used to cut through a scribe line region (e.g., a scribe line region 204) of the substrate stack laterally adjacent to the groove, as described herein.

Process 900 may include additional implementations, such as any single implementation or any combination of implementations described below and/or in connection with one or more other processes described elsewhere herein.

In a first implementation, process 900 includes forming another groove through a portion of the scribe line region in the second substrate and into a portion of the scribe line region in the first substrate.

In a second implementation, alone or in combination with the first implementation, cutting through a scribe line region includes cutting through the other groove in the scribe line region.

In a third implementation, alone or in combination with one or more of the first and second implementations, a lateral width (e.g., a dimension D4) of the groove is less than a lateral width (e.g., a dimension D5) of the other groove.

In a fourth implementation, alone or in combination with one or more of the first through third implementations, process 900 includes forming a third buffer region (e.g., a buffer region 108) laterally between the first buffer region and the first seal ring region, where a density of metallization structures in the third buffer region is greater than a density of metallization structures in the first buffer region, and forming a fourth buffer region (e.g., a buffer region 108) laterally between the second buffer region and the second seal ring region, where a density of metallization structures in the fourth buffer region is greater than a density of metallization structures in the second buffer region.

In a fifth implementation, alone or in combination with one or more of the first through fourth implementations, the first buffer region includes a dielectric region (e.g., a dielectric region 130) that is free of metallization structures, and wherein the second buffer region comprises another dielectric region (e.g., a dielectric region 130) that is free of metallization structures.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

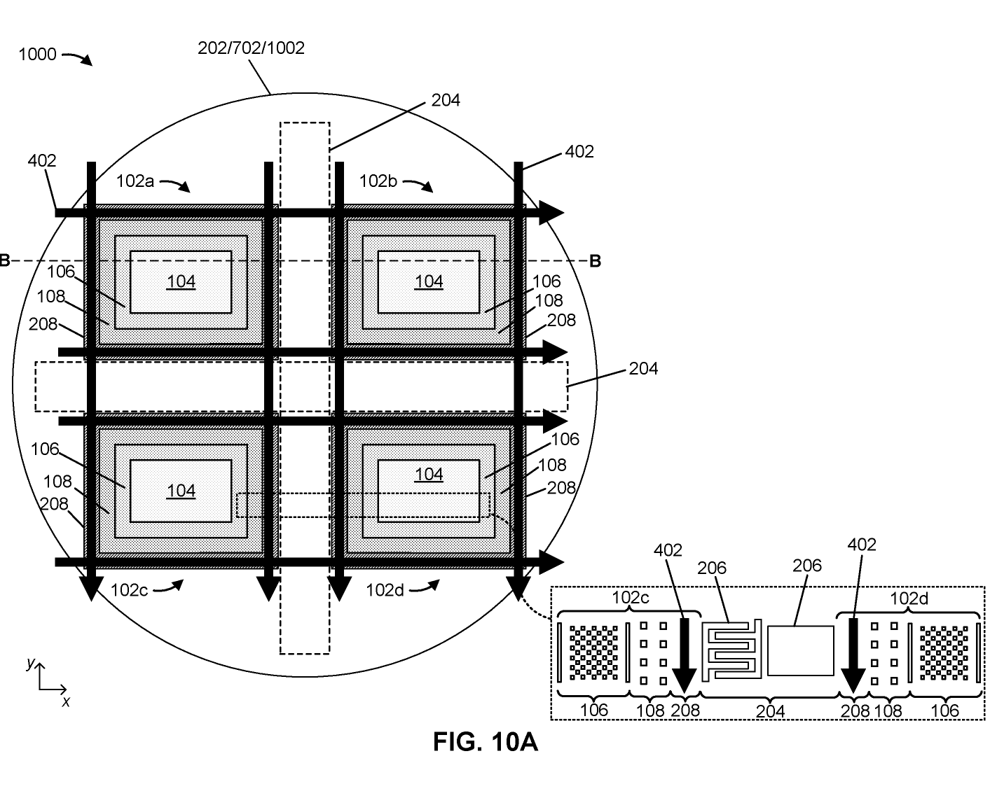

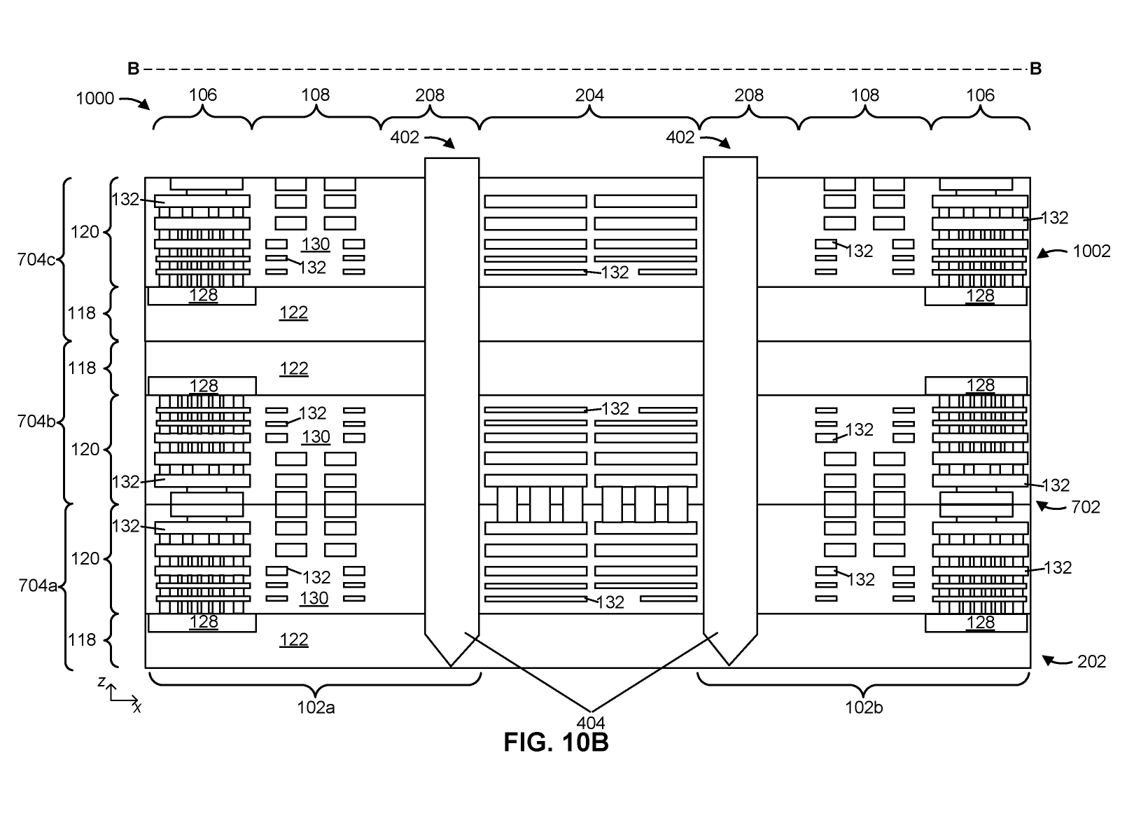

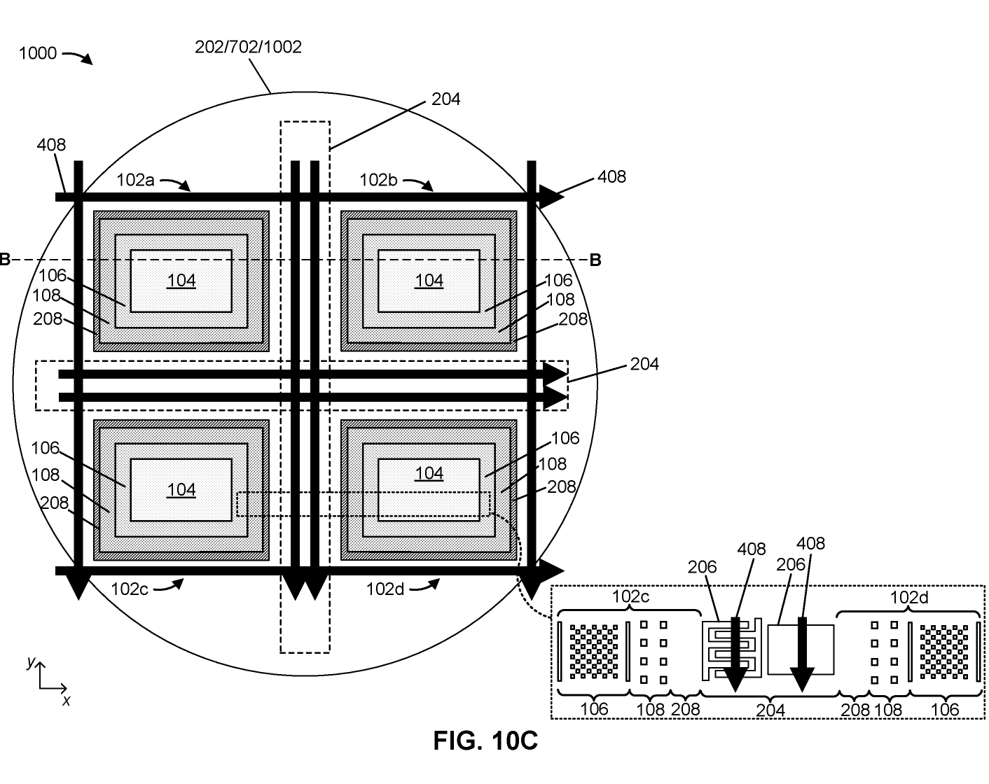

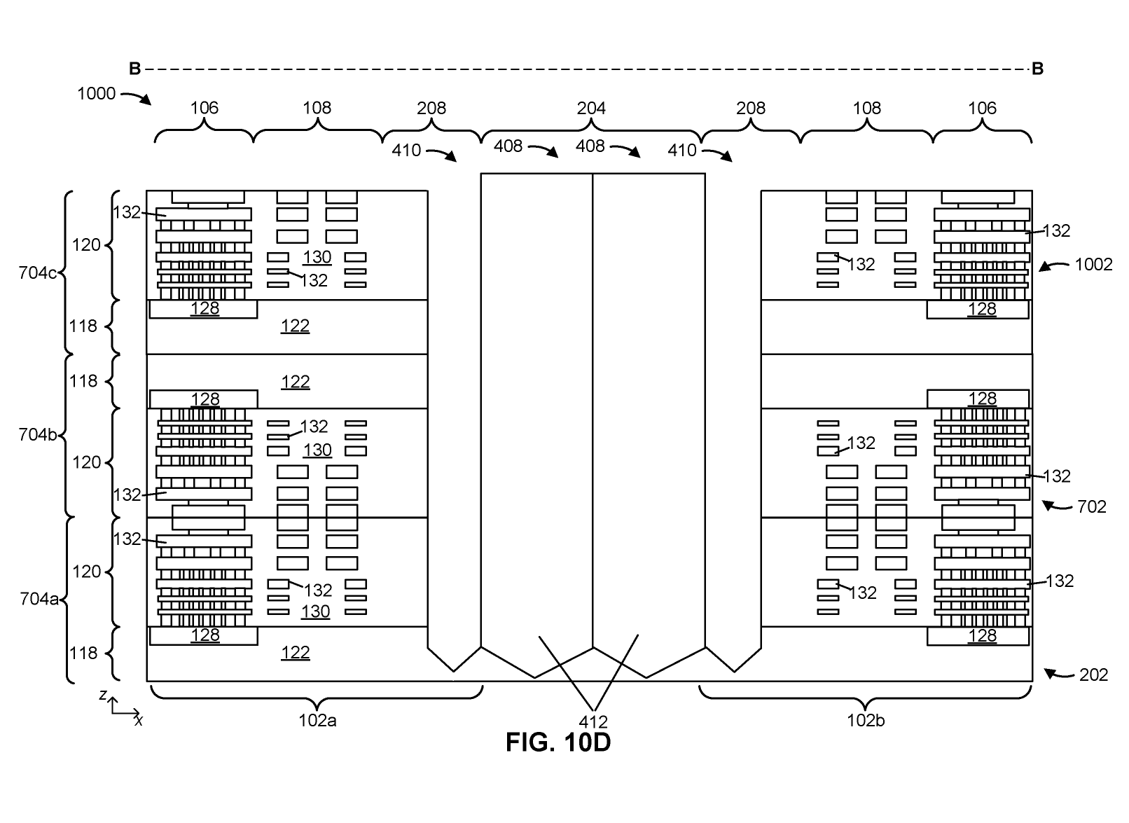

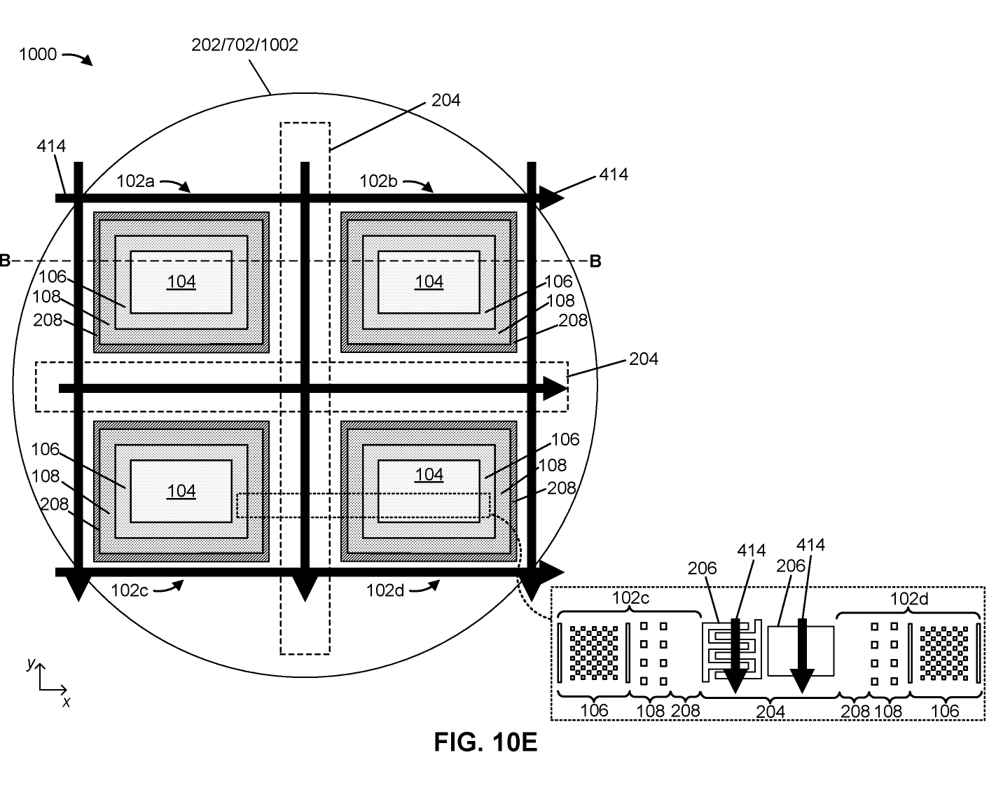

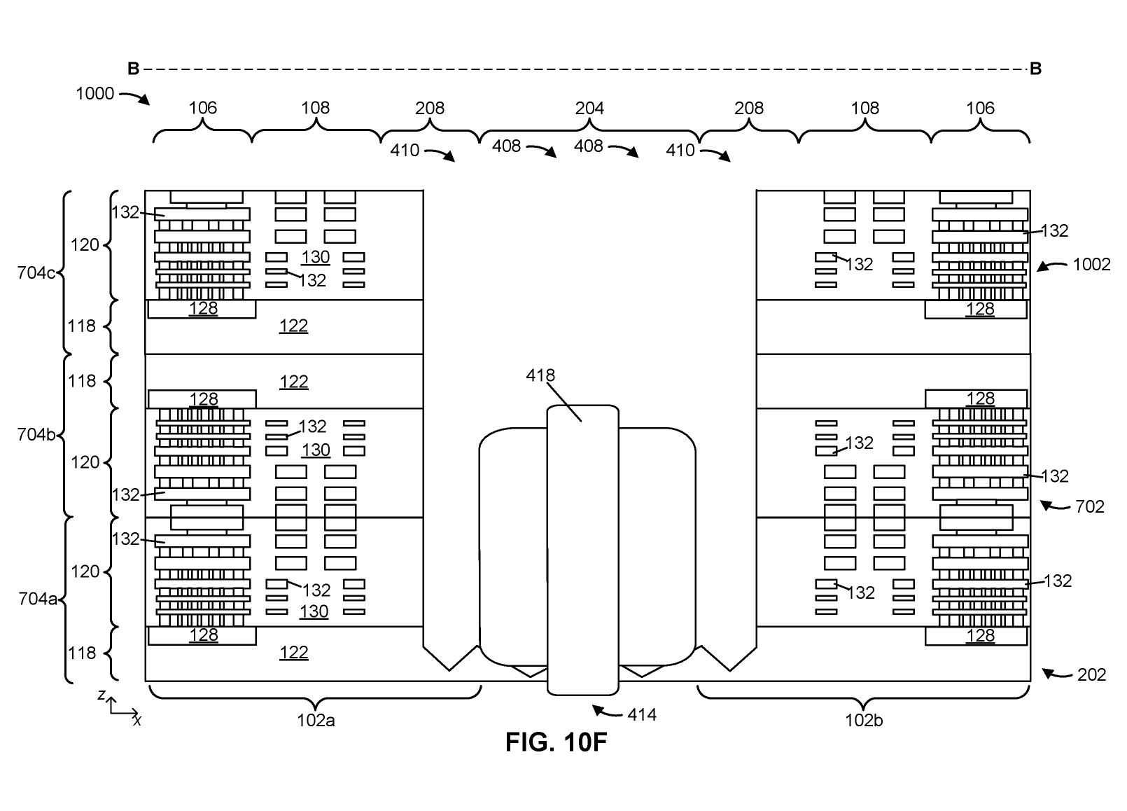

FIGS. 10A-10F are diagrams of an example implementation 1000 of a die singulation process for singulating semiconductor devices 102 from a wafer stack described herein. One or more of the operations described in connection with FIGS. 10A-10F may be performed using one or more semiconductor processing tools, such as a wafer/die transport tool, a laser grooving tool, a wafer sawing tool, and/or another semiconductor processing tool.

As shown in FIGS. 10A-10F, the example implementation 1000 of the die singulation process is similar to the example implementation 700 of the die singulation process illustrated in FIGS. 7A-7F. However, in the example implementation 1000 of the die singulation process, the wafer 202 is bonded with another wafer 702, and the wafer 702 is bonded to a wafer 1002 to form the wafer stack, and the semiconductor devices 102a-102d are singulated from the wafer stack by the die singulation process.

As shown in FIG. 10B, a semiconductor device 102 (e.g., a semiconductor device 102a) may be formed by bonding a semiconductor die 704a and another semiconductor die 704b such that the semiconductor dies 704a and 704b are stacked and vertically arranged in the semiconductor device 102, and by bonding the semiconductor die 704b and another semiconductor die 704c such that the semiconductor dies 704b and 704c are stacked and vertically arranged in the semiconductor device 102.

The semiconductor die 704a may be formed on the wafer 202 according to similar operations described in connection with FIGS. 3A-3C, the semiconductor die 704b may be formed on the wafer 702 according to similar operations described in connection with FIGS. 3A-3C, and the semiconductor die 704c may be formed on the wafer 702 according to similar operations described in connection with FIGS. 3A-3C.

The wafers 202 and 702 may be bonded together such that dielectric-to-dielectric bonds are formed between the dielectric regions 130 of the semiconductor dies 704a and 704b, and such that metal-to-metal bonds are formed between metallization structures 132 of the semiconductor dies 704a and 704b. The wafers 702 and 1002 may be bonded together such that dielectric-to-dielectric bonds are formed between the dielectric regions 130 of the semiconductor dies 704b and 704c, and such that metal-to-metal bonds are formed between metallization structures 132 of the semiconductor dies 704b and 704c.

A device region 104 of a semiconductor device 102 (e.g., the semiconductor device 102a) may be laterally surrounded by a seal ring region 106 that extends through the semiconductor dies 704a, 704b, and 704c. A buffer region 108 of the semiconductor device 102 may extend through the semiconductor dies 704a, 704b, and 704c and may laterally surround the seal ring region 106, and another buffer region 208 of the semiconductor device 102 may extend through the semiconductor dies 704a, 704b, and 704c, and laterally surround the buffer region 108.

As shown in FIG. 10D, the grooves 410 formed in the buffer regions 208 of the semiconductor devices 102a-102d may extend through the semiconductor dies 704c and 704b of the semiconductor devices 102a-102d, and into the semiconductor dies 704a of the semiconductor devices 102a-102d.

As shown in FIG. 10F, the grooves 416 formed in the scribe line regions 204 of the wafer stacks may extend through the semiconductor dies 704c and 704b of the semiconductor devices 102a-102d and into the semiconductor dies 704a of the semiconductor devices 102a-102d. As further shown in FIG. 10F, the saw blade 418 may be passed through the grooves 416 through the remaining portions of the substrate layer 122 of the wafer 202.

As indicated above, FIGS. 10A-10F are provided as an example. Other examples may differ from what is described with regard to FIGS. 10A-10F. For example, the quantity of semiconductor dies stacked together to form semiconductor devices 102 described herein, such as those illustrated in connection with FIGS. 7A-7F and 10A 10F, are examples. Other quantities of semiconductor dies may be stacked together to form semiconductor devices 102 described herein and singulated using techniques described herein.

In this way, semiconductor devices are manufactured on a wafer to include one or more buffer regions that may be used for dicing or cutting the semiconductor devices from the wafer in a die singulation process. The buffer region(s) of a semiconductor device may be located between a scribe line region of the wafer and a seal ring region of the semiconductor device. The seal ring region may laterally surround a device region of the semiconductor device, and the buffer region(s) may laterally surround the seal ring region of the semiconductor device. A laser beam may be used to cut a groove into the buffer region(s) of the semiconductor device as opposed to cutting the groove into the scribe line regions of the wafer. Another laser beam and/or a wafer saw may then be used to cut fully through the scribe line regions to dice or cut the wafer into individual semiconductor devices. The pattern density (e.g., the density of structures) in the buffer region(s) is less than the pattern density in the scribe line regions and in the device region. The lower pattern density in the buffer region(s) provides fewer paths through which heat and mechanical vibration from laser cutting and/or sawing can propagate into the device region of the semiconductor device. In other words, the buffer region(s) effectively provide a buffer for the device region from heat and mechanical stresses generated during the die singulation process, which reduces the likelihood that these other mechanical stresses generated from the die singulation process may lead to cracking, delamination, and/or other types of physical damage to the layers and/or structures of the semiconductor devices. In this way, the buffer region(s) described herein may reduce the defect rate, increase reliability, and/or increase the yield for semiconductor devices manufactured on the wafer.

As described in greater detail above, some implementations described herein provide a method. The method includes forming a plurality of semiconductor devices on a wafer, where each of the plurality of semiconductor devices is manufactured to include a device region, a seal ring region laterally surrounding the device region, and a buffer region laterally surrounding the seal ring region. The method includes forming plurality of scribe line regions laterally between the plurality of semiconductor devices, where a scribe line region of the plurality of scribe line regions is located laterally between a first buffer region of a first semiconductor device of the plurality of semiconductor devices and a second buffer region of a second semiconductor device of the plurality of semiconductor devices. The method includes forming a first groove into the first buffer region and a second groove into the second buffer region. The method includes cutting through the scribe line region between the first groove and the second groove.

As described in greater detail above, some implementations described herein provide a semiconductor device. The semiconductor device includes a device region. The semiconductor device includes a plurality of integrated circuit devices in the device region. The semiconductor device includes a seal ring region laterally surrounding the device region, where the seal ring region includes a plurality of metallization structures. The semiconductor device includes a buffer region laterally adjacent to one or more sides of the seal ring region such that the seal ring region is laterally between the buffer region and the device region, where a density of the plurality metallization structures in the seal ring region is greater than a density of metallization structures in the buffer region.

As described in greater detail above, some implementations described herein provide a method. The method includes forming a first semiconductor die of a semiconductor device in a first substrate, where the first semiconductor die is manufactured to include a first device region, a first seal ring region laterally surrounding the first device region, and a first buffer region laterally surrounding the first seal ring region. The method includes forming a second semiconductor die of the semiconductor device in a second substrate, where the second semiconductor die is manufactured to include a second device region, a second seal ring region laterally surrounding the second device region, and a second buffer region laterally surrounding the second seal ring region. The method includes bonding the first substrate to the second substrate to form a substrate stack, where the first semiconductor die of the semiconductor device is bonded with the second semiconductor die of the semiconductor device. The method includes forming a groove through the second buffer region of the second semiconductor die and into the first buffer region of the first semiconductor die. The method includes cutting through a scribe line region of the substrate stack laterally adjacent to the groove.

As described in greater detail above, some implementations described herein include a method. The method includes forming a first semiconductor die of a semiconductor device in a first substrate. The first semiconductor die is manufactured to include a first device region, a first seal ring region laterally surrounding the first device region, and a first buffer region laterally surrounding the first seal ring region. The first buffer region comprises a first dielectric region that is free of metallization structures. The method includes forming a second semiconductor die of the semiconductor device in a second substrate. The second semiconductor die is manufactured to include a second device region, a second seal ring region laterally surrounding the second device region, and a second buffer region laterally surrounding the second seal ring region. The second buffer region comprises a second dielectric region that is free of metallization structures. The method includes bonding the first substrate to the second substrate to form a substrate stack. The first semiconductor die of the semiconductor device is bonded with the second semiconductor die of the semiconductor device. The method includes forming a groove through the second dielectric region of the second buffer region and into the first dielectric region of the first buffer region. The method includes cutting through a scribe line region of the substrate stack laterally adjacent to the groove.

As described in greater detail above, some implementations described herein include a method. The method includes forming a first semiconductor device to include a first device region, a first seal ring region laterally surrounding the first device region, and a first buffer region laterally surrounding the first seal ring region. The method includes forming a second semiconductor device to include a second device region, a second ring region laterally surrounding the second device region, and a second buffer region laterally surrounding the second seal ring region. The method includes forming a scribe line region laterally between the first buffer region and the second buffer region. The method includes forming a first groove into the first buffer region and a second groove into the second buffer region. The method includes cutting through the scribe line region between the first groove and the second groove.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first semiconductor device to include a first device region, a first seal ring region laterally surrounding the first device region, and a first buffer region laterally surrounding the first seal ring region;
forming a second semiconductor device to include a second device region, a second ring region laterally surrounding the second device region, and a second buffer region laterally surrounding the second seal ring region;
forming a scribe line region laterally between the first buffer region and the second buffer region;
forming a first groove into the first buffer region and a second groove into the second buffer region; and
cutting through the scribe line region between the first groove and the second groove.

2. The method of claim 1, wherein cutting through the scribe line region comprises:
cutting through the scribe line region after forming the first groove and the second groove.

3. The method of claim 1, wherein cutting through the scribe line region comprises:
forming a third groove into the scribe line region; and
cutting through the third groove.

4. The method of claim 1, wherein forming the first groove and the second groove comprises:
performing a laser cutting operation to form the first groove and the second groove.

5. The method of claim 4, wherein cutting through the scribe line region comprises:
performing another laser cutting operation, after the laser cutting operation, to form a third groove into the scribe line region.

6. The method of claim 5, wherein cutting through the scribe line region comprises:
performing a sawing operation, after the other laser cutting operation, to cut through the third groove.

7. The method of claim 1, wherein forming the first semiconductor device comprises:
forming the first semiconductor device such that a density of metallization structures in the first buffer region is less than a density of metallization structures in the first seal ring region, and such that the density of metallization structures in the first buffer region is less than a density of metallization structures in the scribe line region.

8. A semiconductor device, comprising:
a device region;
a seal ring region laterally surrounding the device region,
wherein the seal ring region comprises a plurality of metallization structures; and
a buffer region laterally adjacent to one or more sides of the seal ring region such that the seal ring region is between the buffer region and the device region,
wherein a density of the plurality metallization structures in the seal ring region is greater than a density of metallization structures in the buffer region.

9. The semiconductor device of claim 8, wherein the buffer region laterally surrounds the seal ring region.

10. The semiconductor device of claim 8, wherein the buffer region is a first buffer region of the semiconductor device; and
wherein the semiconductor device further comprises a second buffer region laterally adjacent to one or more sides of the first buffer region,
wherein the first buffer region is located laterally between the second buffer region and the seal ring region.

11. The semiconductor device of claim 10, wherein the density of metallization structures in the first buffer region is greater than a density of metallization structures in the second buffer region.

12. The semiconductor device of claim 10, wherein the density of metallization structures in the first buffer region and a density of metallization structures in the second buffer region are approximately equal.

13. The semiconductor device of claim 10, wherein a width of the first buffer region, in a direction that is approximately perpendicular to a length of the first buffer region, is greater than a width of the second buffer region in a direction that is approximately perpendicular to a length of the second buffer region.

14. The semiconductor device of claim 10, wherein the first buffer region extends along a greater quantity of sides of the seal ring region than the second buffer region.

15. A method, comprising:
forming a first semiconductor die of a semiconductor device in a first substrate,
wherein the first semiconductor die includes a first device region, a first seal ring region laterally surrounding the first device region, and a first buffer region laterally surrounding the first seal ring region, and
wherein the first buffer region comprises a first dielectric region that is free of metallization structures;
forming a second semiconductor die of the semiconductor device in a second substrate,
wherein the second semiconductor die includes a second device region, a second seal ring region laterally surrounding the second device region, and a second buffer region laterally surrounding the second seal ring region, and
wherein the second buffer region comprises a second dielectric region that is free of metallization structures;
bonding the first substrate to the second substrate to form a substrate stack,
wherein the first semiconductor die of the semiconductor device is bonded with the second semiconductor die of the semiconductor device;
forming a groove through the second dielectric region of the second buffer region and into the first dielectric region of the first buffer region; and
cutting through a scribe line region of the substrate stack laterally adjacent to the groove.

16. The method of claim 15, further comprising:
forming another groove through a portion of the scribe line region in the second substrate and into a portion of the scribe line region in the first substrate.

17. The method of claim 16, wherein cutting through a scribe line region comprises:
cutting through the other groove in the scribe line region.

18. The method of claim 16, wherein a lateral width of the groove is less than a lateral width of the other groove.

19. The method of claim 15, further comprising:
forming a third buffer region laterally between the first buffer region and the first seal ring region,
wherein a density of metallization structures in the third buffer region is greater than a density of metallization structures in the first buffer region.

20. The method of claim 19, further comprising:
forming a fourth buffer region laterally between the second buffer region and the second seal ring region,
wherein a density of metallization structures in the fourth buffer region is greater than a density of metallization structures in the second buffer region.
